(19) United States
(12) Patent Application Publication
(10) Pub. No.: US 2026/0344073 A1
(43) Pub. Date: Oct. 29, 2026

(54) IMAGE SENSOR AND METHOD OF MANUFACTURING THE SAME

(71) Applicant: Taiwan Semiconductor Manufacturing Company, Ltd., Hsinchu (TW)

(72) Inventors: Sin-Yi Jiang, Hsinchu City (TW); Po-Chun Liu, Hsinchu City (TW); Yi-Shin Chu, Hsinchu City (TW); Hsiang-Lin Chen, Hsinchu County (TW); Yin-Kai Liao, Taipei City (TW); Sung-Wen Huang Chen, Nantou County (TW); Hsing-Chih Lin, Tainan City (TW)

(21) Appl. No.: 19/186,937

(22) Filed: Apr. 23, 2025

(51) Int. Cl. H10F 39/00; H10F 39/18

(52) U.S. Cl. CPC H10F 39/8033; H10F 39/014; H10F 39/028; H10F 39/184

(57) ABSTRACT

Various embodiments of the present disclosure are directed towards an image sensor. The image sensor includes a substrate comprising a first material. A semiconductor layer is on the substrate and comprising a second material different from the first material. A doped cap layer is on a top surface of the semiconductor layer and comprises a first doping type. A doped peripheral region is in the substrate and on opposing sides of the semiconductor layer. The doped peripheral region comprises the first doping type.

### BACKGROUND

Image sensors are solid-state devices that are configured to convert incoming light into an electrical signal. The electrical signal is then provided to a processor that can convert the electrical signal to data that can be stored and/or viewed by a user. Integrated chips (ICs) with image sensors are used in a wide range of modern-day electronic devices, such as cell phones, cameras, medical devices, etc.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIG. 1 illustrates a cross-sectional view of some embodiments of an image sensor comprising a doped cap layer over a semiconductor layer of a photodetector and a doped peripheral region adjacent to outer edges of the semiconductor layer.

FIGS. 2A and 2B illustrate various views of some other embodiments of an image sensor comprising a doped cap layer over a semiconductor layer of a photodetector and a doped peripheral region adjacent to outer edges of the semiconductor layer.

FIG. 2C illustrates a cross-sectional view of some embodiments of a section of the image sensor of FIG. 2A.

FIGS. 3A and 3B illustrate various views of some other embodiments of an image sensor comprising a doped cap layer over a semiconductor layer of a photodetector and a doped peripheral region adjacent to outer edges of the semiconductor layer.

FIGS. 4A and 4B illustrate various cross-sectional views of some other embodiments of an image sensor comprising a doped cap layer over a semiconductor layer of a photodetector and a doped peripheral region adjacent to outer edges of the semiconductor layer.

FIGS. 5A through 5E illustrate cross-sectional views of some other embodiments of the image sensor of FIG. 2A.

FIGS. 6A and 6B through 19A and 19B illustrate a series of various views of some embodiments of a method for forming an image sensor comprising a doped cap layer over a semiconductor layer of a photodetector and a doped peripheral region adjacent to outer edges of the semiconductor layer.

FIG. 20 illustrates a block diagram of some embodiments of the method of FIGS. 6A and 6B through 19A and 19B.

FIGS. 21-28 illustrate a series of cross-sectional views of some other embodiments of a method for forming an image sensor comprising a doped cap layer over a semiconductor layer of a photodetector and a doped peripheral region adjacent to outer edges of the semiconductor layer.

FIGS. 29-38 illustrate a series of cross-sectional views of some further embodiments of a method for forming an image sensor comprising a doped cap layer over a semiconductor layer of a photodetector and a doped peripheral region adjacent to outer edges of the semiconductor layer.

FIG. 39 illustrates a block diagram of some embodiments of the method of FIGS. 29-38.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

Image sensor integrated chips (ICs) may comprise photodetectors configured to detect infrared (IR) radiation. This facilitates the image sensor ICs being employed in time-of-flight (ToF) depth sensing or other suitable applications. However, image sensor ICs typically comprise silicon based photodetectors. Silicon has a large bandgap, where the absorption coefficient of silicon decreases as a wavelength of radiation increases. As a result, silicon-based photodetectors may have low quantum efficiency (QE) for IR radiation. To increase QE for IR radiation, silicon based photodetectors may be replaced by, for example, germanium based photodetectors. Germanium has a small bandgap compared to silicon and therefore has higher absorption in the IR spectrum compared to silicon. Thus, germanium based photodetectors have high QE for IR radiation.

An image sensor IC employed for a ToF application may include a photodetector comprising a semiconductor layer and a cap layer. The semiconductor layer is on or recessed in a top of a substrate and the cap layer overlies the semiconductor layer. The substrate and the cap layer comprise a first material (e.g., silicon) and the semiconductor layer comprises a second material (e.g., germanium) having a smaller bandgap than that of the first material. The smaller bandgap of the second material increases QE for IR radiation. However, it has been appreciated that different lattice constants between the first material and the second material may lead to defects (e.g., dislocation defects) along an interface between the semiconductor layer and the substrate and the semiconductor layer and the cap layer. The defects can cause dark current leakage within the photodetector, which negatively impacts performance of the photodetector (e.g., reduces a signal-to-noise ratio (SNR), QE, or the like of the photodetector). For example, mobile charge carriers (e.g., mobile electrons) of the dark current may collect at one of more doped regions of the photodetector utilized to measure incident radiation, thereby leading to inaccuracies in depth sensing.

In an effort to decrease the dark current leakage, an upper doped region may be formed (e.g., by an ion implantation process) in the cap layer and/or the semiconductor layer. The upper doped region may, for example, be configured as a first contact region for the photodetector and may comprise a first doping type (e.g., p-type) configured to passivate the mobile charge carriers of the dark current. However, due to processing tool limitations during the ion implantation process utilized to form the upper doped region, proper alignment of the upper doped region at the interfaces between the semiconductor layer, the substrate, and the cap layer may not be achieved. This reduces an ability for the upper doped region to mitigate issues from the dark current. Further, dopants from the upper doped region may be driven into the substrate and/or the semiconductor layer and at/around a channel region of the photodetector, instead of remaining at or around the interfaces between the semiconductor layer, the substrate, and the cap layer. As a result, the upper doped region may not effectively passivate the mobile charge carriers of the dark current and/or may negatively impact an electric field in the photodetector during operation, thereby decreasing a performance of the image sensor IC.

Various embodiments of the present disclosure are directed towards an image sensor having a doped cap layer and a doped peripheral region configured to reduce dark current and increase an overall performance of the image sensor. In some embodiments, the image sensor comprises a semiconductor layer over a substrate. The substrate and the doped cap layer comprise a first material (e.g., silicon) and the semiconductor layer comprises a second material (e.g., germanium) having a smaller bandgap than the first material. During fabrication of the image sensor, the doped cap layer is formed over the semiconductor layer and is in-situ doped with a relatively high doping concentration (e.g., about 1×10¹⁹ atoms/cm³ or greater) of one or more first dopants. After forming the doped cap layer, an annealing process is performed to drive the one or more first dopants from the doped cap layer into interfaces between the doped cap layer, the semiconductor layer, and the substrate, thereby forming a doped peripheral region in the substrate and at outer edges of the doped cap layer and/or semiconductor layer. By virtue of the doped peripheral region being formed by the annealing process instead of some other process (e.g., an ion implantation process), the doped peripheral region may be more accurately aligned with the interfaces between doped cap layer, the semiconductor layer, and the substrate. Further, forming the doped peripheral region by the annealing process may facilitate a peak doping concentration of the doped peripheral region being relatively close to the interfaces. As a result, the doped peripheral region may effectively reduce dark current by drawing the mobile charge carriers (e.g., mobile electrons) of the dark current away from an active region (e.g., a channel region) of the photodetector. Thus, an overall performance of the image sensor is increased.

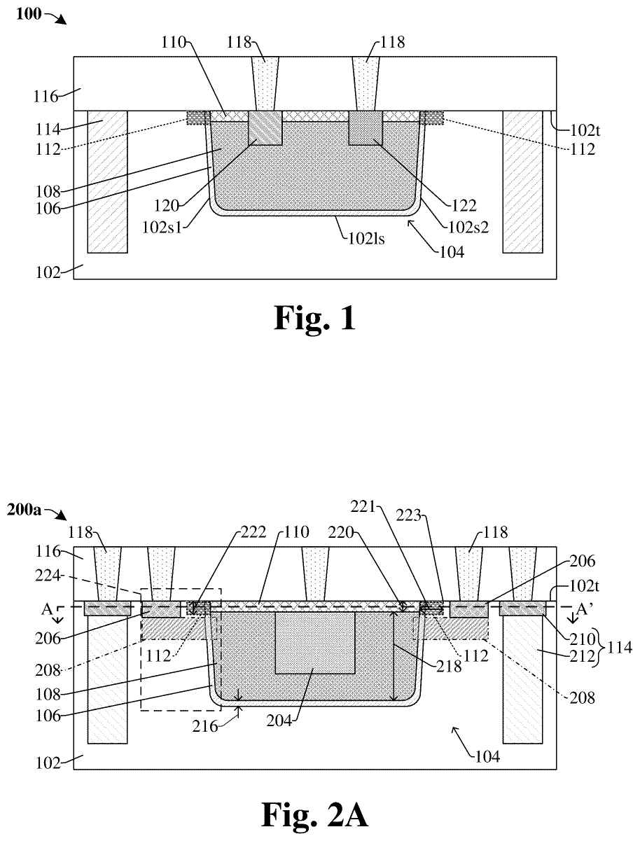

FIG. 1 illustrates a cross-sectional view 100 of some embodiments of an image sensor comprising a doped cap layer 110 over a semiconductor layer 108 of a photodetector 104 and a doped peripheral region 112 adjacent to outer edges of the semiconductor layer 108. In some embodiments, the image sensor may be part of an integrated chip (IC) and/or may be referred to as an IC or and image sensor IC.

The image sensor comprises a substrate 102 and a photodetector 104 comprising a semiconductor layer disposed on and/or within the substrate 102. For example, the substrate 102 may have one or more surfaces defining a recess that extends into a top surface 102t of the substrate 102. In some embodiments, the substrate 102 comprises opposing sidewalls 102s1, 102s2 and a lower surface 102l that defines the recess, where the semiconductor layer 108 is disposed in the recess. The photodetector 104 further comprises doped regions 120, 122 in the semiconductor layer 108. The doped cap layer 110 overlies the semiconductor layer 108. The substrate 102 and the doped cap layer 110 comprise a first material. The first material may, for example, be or comprise silicon or some other suitable semiconductor material(s). The semiconductor layer 108 comprises a second material different from the first material. The second material may, for example, be or comprise germanium, silicon germanium, or some other suitable semiconductor material(s). In some embodiments, a bulk of the semiconductor layer 108 is undoped. For example, the bulk of the semiconductor layer 108 comprises an intrinsic form of the second material (e.g., intrinsic germanium). In further embodiments, the bulk of the semiconductor layer 108 is doped with a first doping type (e.g., p-type) having a doping concentration equal to or less than approximately 1×10¹⁵ atoms per cubic centimeter (atoms/cm³) or some other suitable value. In some embodiments, a bulk of the substrate 102 is doped with the first doping type (e.g., p-type) having a doping concentration equal to or less than approximately 1×10¹⁵ atoms/cm³ or some other suitable value.

An interlayer 106 is arranged between the semiconductor layer 108 and the substrate 102. In some embodiments, the interlayer 106 extends along the opposing sidewalls 102s1, 102s2 and the lower surfaces 102ls of the substrate 102. In some embodiments, the interlayer 106 comprises the first material (e.g., silicon). In various embodiments, a bulk of the interlayer 106 is undoped. A dielectric structure 116 overlies the substrate 102. A plurality of conductive contacts 118 are arranged in the dielectric structure 116 and overlie the doped regions 120, 122. An isolation structure 114 is arranged in the substrate 102 on opposing sides of the semiconductor layer 108. The isolation structure 114 is configured to increase optical and/or electrical isolation between the photodetector 104 and adjacent photodetectors (not shown).

The doped cap layer 110 is arranged between the semiconductor layer 108 and the dielectric structure 116. In some embodiments, the doped cap layer 110 continuously extends along a top surface of the semiconductor layer 108 and contacts inner opposing sidewalls of the interlayer 106. The doped cap layer 110 may, for example, be or comprise silicon, epitaxial silicon, or some other suitable material. In various embodiments, the doped cap layer 110 comprises the first doping type (e.g., p-type) having a relatively high doping concentration that is greater than approximately 1×10¹⁹ atoms/cm³, within a range of 1×10¹⁹ to 1×10²¹, or some other suitable value. The doping concentration of the doped cap layer 110 is greater than the doping concentration of the bulk of the substrate 102 and/or the doping concentration of the bulk of the semiconductor layer 108.

In various embodiments, the doped regions 120, 122 includes a first doped region 120 and a second doped region 122. The first doped region 120 comprises the first doping type (e.g., p-type) and the second doped region 122 comprises a second doping type (e.g., n-type) opposite the first doping type. In some embodiments, the first doping type is p-type and the second doping type is n-type. In various embodiments, the first and second doped regions 120, 122 extend from the doped cap layer 110 to the semiconductor layer 108. In some embodiments, the first and second doped regions 120, 122 respectively have a doping concentration within a range of approximately 1×10¹⁶ to 1×10¹⁷ atoms/cm³ or some other suitable value.

The doped peripheral region 112 is arranged in the substrate 102 on opposing sides of the doped cap layer 110 and/or on opposing sides of the semiconductor layer 108. In some embodiments, the doped peripheral region 112 continuously extends from a corresponding sidewall of the doped cap layer 110, through the interlayer 106, into the substrate 102. The doped peripheral region 112 may be ring-shaped when viewed in top view and extends around outer perimeters of the doped cap layer 110 and the semiconductor layer 108. In some embodiments, a doping concentration of the doped peripheral region 112 is greater than the doping concentrations of the first and second doped regions 120, 122.

During operation of the image sensor, incident electromagnetic radiation that strikes the semiconductor layer 108 can cause an electron-hole pair to be generated in the semiconductor layer 108. Bias voltages may be applied to the first and second doped regions 120, 122 to form an electric field within the semiconductor layer 108. The electric field can move an electron released from the generation of the electron-hole pair to the second doped region 122, thereby generating a photocurrent. The generated photocurrent may be detected and/or read by readout circuitry (not shown). Thus, the photodetector 104 is configured to convert the incident electromagnetic radiation into electrical signals. The semiconductor layer 108 comprising the second material (e.g., germanium) with a relatively small bandgap (e.g., less than that of the first material) facilitates the photodetector 104 having increased absorption of IR radiation (e.g., radiation having a wavelength that is in a range of approximately 700 to 3,000 nm). As a result, the photodetector 104 comprising the semiconductor layer 108 with the second material (e.g., germanium) increases a QE of the photodetector 104 for IR radiation. In some embodiments, the photodetector 104 may be configured as a PIN photodiode, a PN photodiode, an avalanche photodiode, a depth sensor, or the like.

During fabrication of the image sensor, in some embodiments, the doped cap layer 110 is formed on the semiconductor layer 108 and is in-situ doped with the first doping type (e.g., p-type). After forming the doped cap layer 110, an annealing process is performed to drive dopants from the doped cap layer 110 into interfaces between the doped cap layer 110, the semiconductor layer 108, the interlayer 106, and the substrate 102, thereby forming the doped peripheral region 112. Accordingly, the doped peripheral region 112 is accurately aligned with the interfaces between the doped cap layer 110, the semiconductor layer 108, the interlayer 106, and the substrate 102. In various embodiments, forming the doped peripheral region 112 with the annealing process facilitates a peak doping concentration of the doped peripheral region 112 being closer to an interface between the semiconductor layer 108 and the substrate 102. As a result of the doped peripheral region 112 having the first doping type (e.g., p-type) and being accurately aligned at the interfaces between the semiconductor layer 108 and the substrate 102, the doped peripheral region 112 may effectively reduce issues due to dark current. For example, the doped peripheral region 112 may effectively draw mobile charge carriers (e.g., mobile electrons) of the dark current away from an active region of the semiconductor layer 108 (e.g., a middle region of the semiconductor layer 108 between the first and second doped regions 120, 122). This neutralizes the mobile charge carriers of the dark current, such that dark current is reduced and may not collect at the second doped region 122. Thus, measurements of the photodetector 104 are more accurate and hence distance and/or depth sensing is more accurate. Accordingly, an overall performance of the image sensor is increased.

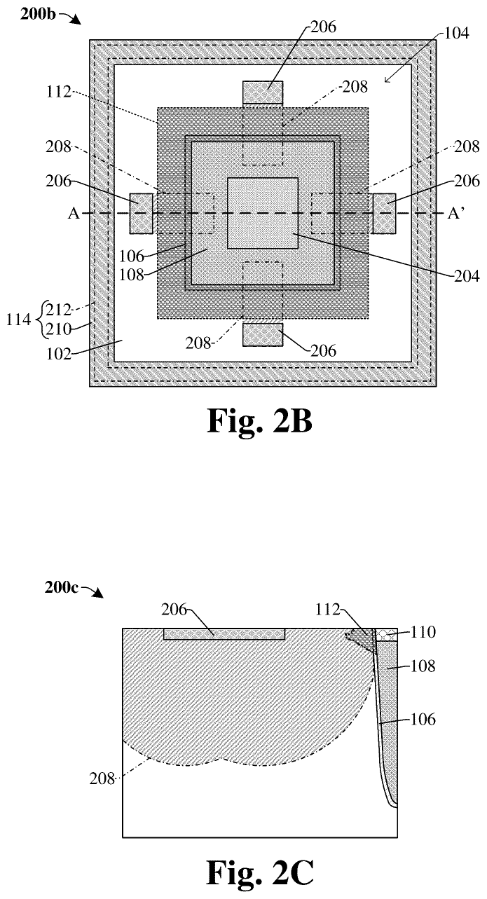

FIG. 2A illustrates a cross-sectional view 200a of some other embodiments of an image sensor comprising a doped cap layer 110 over a semiconductor layer 108 of a photodetector 104 and a doped peripheral region 112 adjacent to outer edges of the semiconductor layer 108. The image sensor of FIG. 2A may correspond to some other embodiments of the image senor of FIG. 1.

In some embodiments, the photodetector 104 comprises the semiconductor layer 108, a plurality of first contact regions 206, the doped cap layer 110, a plurality of outer lateral wells 208, and a middle well region 204. A bulk of the substrate 102 comprises the first doping type (e.g., p-type). The plurality of first contact regions 206 are disposed in the substrate 102 on opposing sides of the semiconductor layer 108. The plurality of first contact regions 206 comprise the second doping type (e.g., n-type). In various embodiments, each of the first contact regions 206 are spaced between the semiconductor layer 108 and a corresponding side of the isolation structure 114. The first contact regions 206 are laterally offset from the interlayer 106. Further, the first contact regions 206 continuously extend from the top surface 102t of the substrate 102 to a point below the top surface 102t.

Each outer lateral well in the plurality of outer lateral wells 208 underlies a corresponding contact region in the plurality of first contact regions 206 and continuously laterally extends from under the corresponding contact region toward the semiconductor layer 108. In various embodiments, the outer lateral wells 208 extend laterally from the substrate 102, through a corresponding upper region of the interlayer 106 into the semiconductor layer 108. The plurality of outer lateral wells 208 comprise the second doping type (e.g., n-type). In various embodiments, the doped cap layer 110 may be configured as a second contact region for the photodetector 104. The doped cap layer 110 comprises the first doping type (e.g., p-type). In some embodiments, a doping concentration of the doped cap layer 110 is greater than a doping concentration of the outer lateral wells 208 and/or a doping concentration of the plurality of first contact regions 206.

The middle well region 204 is arranged in the semiconductor layer 108 below the doped cap layer 110. The middle well region 204 comprises the first doping type (e.g., p-type). In some embodiments, the middle well region 204 continuously extends from a top surface of the semiconductor layer 108 to a point below the top surface of the semiconductor layer 108. In some embodiments, a bulk of the semiconductor layer 108 around the middle well region 204 comprises the first doping type (e.g., p-type) having a doping concentration less than a doping concentration of the middle well region 204. In yet further embodiments, the bulk of the semiconductor layer 108 is undoped. The middle well region 204 is spaced between the outer lateral wells 208. A bottom of the middle well region 204 is disposed below bottoms of the outer lateral wells 208.

The dielectric structure 116 is arranged over the top surface 102t of the substrate 102. In some embodiments, the dielectric structure 116 comprises one or more dielectric layers that may each comprise silicon dioxide, silicon carbide, silicon nitride, some other dielectric material, or any combination of the foregoing. The plurality of conductive contacts 118 are arranged in the dielectric structure 116. In some embodiments, the conductive contacts 118 overlie and are electrically coupled to a corresponding one of the first contact regions 206 and/or the doped cap layer 110. The conductive contacts 118 may, for example, be or comprise copper, aluminum, tungsten, ruthenium, titanium nitride, tantalum nitride, some other conductive material, or any combination of the foregoing.

The isolation structure 114 is arranged in the substrate 102 and continuously wraps around an outer perimeter of the semiconductor layer 108. In some embodiments, the isolation structure 114 comprises an upper doped isolation region 210 and a lower doped isolation region 212 underlying the upper doped isolation region 210. The upper doped isolation region 210 and the lower doped isolation region 212 are doped regions of the substrate 102 that each comprise the first doping type (e.g., p-type). In various embodiments, a doping concentration of the upper doped isolation region 210 is greater than a doping concentration of the lower doped isolation region 212. Further, the doping concentration of the lower doped isolation region 212 is greater than a doping concentration of the bulk of the substrate 102. The isolation structure 114 is configured to increase electrical isolation between the photodetector 104 and other photodetectors (not shown) disposed in the substrate 102.

The doped peripheral region 112 is arranged in the substrate 102 on opposing sides of the semiconductor layer 108. In some embodiments, the doped peripheral region 112 contacts opposing sidewalls of the semiconductor layer 108 and opposing sidewalls of the semiconductor layer 108. In various embodiments, the doped peripheral region 112 continuously extends through a thickness 216 of the interlayer 106 into the substrate 102. The doped peripheral region 112 comprises the first doping type (e.g., p-type).

During operation of the image sensor, incident electromagnetic radiation that strikes the semiconductor layer 108 can cause an electron-hole pair to be generated in the semiconductor layer 108. Bias voltages may be applied to the first contact regions 206 and the doped cap layer 110 to generate an electric field in the semiconductor layer 108, where the electric field can move a released electron (e.g., released from generation of the electron-hole pair) to the outer lateral wells 208, thereby generating a photocurrent that may be detected and/or read by readout circuitry (not shown). In various embodiments, the first contact regions 206 may be biased with 0 volts (V) and the doped cap layer 110 may be biased with −0.1 to −5 V, it will be appreciated that other bias voltages are amenable. Thus, in some embodiments, the released electron may travel laterally from a middle region of the semiconductor layer 108 (e.g., from the middle well region 204) to the outer lateral wells 208. By virtue of at least a location, doping type, and/or doping concentration of the doped peripheral region 112, dark current in the photodetector 104 (e.g., due to defects at interfaces between the substrate 102 and the semiconductor layer 108) may be reduced and the electric field in the semiconductor layer 108 may be enhanced. In some embodiments, because the outer lateral wells 208 are arranged on opposing lateral sides of the semiconductor layer 108, the reduction of dark current due to defects at the interfaces between the substrate 102 and the semiconductor layer 108 increases performance of the photodetector 104. For example, defects at the interfaces between the semiconductor layer 108 and the substrate 102 may cause a high generation of mobile electrons (e.g., through thermal generation) at or near the outer lateral wells 208. In such instances, it is difficult to distinguish the mobile electrons from electrons released in the semiconductor layer 108 from incident electromagnetic radiation. The doped peripheral region 112 may, for example, be configured to neutralize the mobile charge carriers of the dark current, thereby reducing dark current and increasing a performance (e.g., increasing a QE, SNR, etc.) of the photodetector 104. As a result, an overall performance of the image sensor is increased.

In some embodiments, the middle well region 204, the bulk of the substrate 102, the bulk of the semiconductor layer 108, the doped cap layer 110, the doped peripheral region 112, the upper doped isolation region 210, and the lower doped isolation region 212 comprise one or more first dopants (e.g., boron, aluminum, gallium, or the like) having the first doping type (e.g., p-type). A doping concentration of the doped cap layer 110 may, for example, be greater than approximately 1×10¹⁹ atoms/cm³, within a range of approximately 1×10¹⁹ to 1×10²¹ atoms/cm³, or some other suitable value. A doping concentration of the doped peripheral region 112 may, for example, be equal to or greater than approximately 1×10¹⁶ atoms/cm³, within a range of approximately 1×10¹⁶ to 1×10²⁰ atoms/cm³, or some other suitable value. In some embodiments, the doping concentration of the doped cap layer 110 is greater than the doping concentration of the doped peripheral region 112. A doping concentration of the middle well region 204 may, for example, be within a range of approximately 1×10¹⁶ to 1×10¹⁷ atoms/cm³ or some other suitable value. In some embodiments, the doping concentration of the middle well region 204 is less than the doping concentration of the doped peripheral region 112. A doping concentration of the upper doped isolation region 210 may, for example, be within a range of approximately 1×10¹⁸ to 1×10²⁰ atoms/cm³ or some other suitable value. A doping concentration of the lower doped isolation region 212 may, for example, be within a range of approximately 1×10¹⁶ to 1×10¹⁸ atoms/cm³ or some other suitable value. In various embodiments, the doping concentration of the lower doped isolation region 212 is less than the doping concentration of the upper doped isolation region 210 and/or is less than the doping concentration of the doped peripheral region 112.

In various embodiments, the doping concentration of the doped cap layer 110 has a gaussian doping profile, a gradient doping profile, a uniform doping profile, or the like across a thickness 220 of the doped cap layer 110. In an embodiment in which the doped cap layer 110 has the gradient doping profile, the doping concentration of the doped cap layer 110 may continuously increase from a top surface of the doped cap layer 110 to a bottom surface of the doped cap layer 110. In another embodiment in which the doped cap layer 110 has the gaussian doping profile, a peak of the doping concentration of the doped cap layer 110 may be at or below a middle of the thickness 220 of the doped cap layer 110.

In some embodiments, the first contact regions 206 and the outer lateral wells 208 comprise one or more second dopants (e.g., arsenic, antimony, phosphorus, or the like) having the second doping type (e.g., n-type). A doping concentration of the first contact regions 206 may, for example, be within a range of approximately 1×10¹⁸ to 1×10¹⁹ atoms/cm³ or some other suitable value. A doping concentration of the outer lateral wells 208 may, for example, be within a range of approximately 1×10¹⁶ to 1×10¹⁷ atoms/cm³ or some other suitable value. In some embodiments, the doping concentration of the first contact regions 206 is greater than the doping concentration of the outer lateral wells 208. In further embodiments, the doping concentration of the doped cap layer 110 is greater than the doping concentration of the first contact regions 206. In yet further embodiments, the doping concentration of the doped peripheral region 112 is greater than the doping concentration of the first contact regions 206 and/or is greater than the doping concentration of the outer lateral wells 208.

A thickness 216 of the interlayer 106 is, for example, equal to or greater than approximately 40 nanometers (nm), within a range of approximately 40 to 50 nm, or some other suitable value. A thickness 218 of the semiconductor layer 108 is, for example, equal to or greater than approximately 1 micrometer (um), within a range of approximately 1 to 2 um, or some other suitable value. In some embodiments, the thickness 218 being equal to or greater than 1 um increases a sensing area for the photodetector 104, thereby improving the performance (e.g., the SNR) of the photodetector 104. In further embodiments, the thickness 218 being equal to or less than 2 um facilitates scaling down a size of the photodetector 104. In some embodiments, the semiconductor layer 108 may be referred to as a device layer or an absorption enhancement layer.

In some embodiments, the doped cap layer 110 directly contacts a top surface of the semiconductor layer 108. In various embodiments, a top surface of the doped cap layer 110 is aligned with the top surface 102t of the substrate 102 and/or the doped cap layer 110 contacts inner opposing sidewalls of the interlayer 106. The doped cap layer 110 comprises the first material (e.g., silicon) and is configured to mitigate damage to the semiconductor layer 108 during fabrication of the image sensor. For example, the doped cap layer 110 may mitigate damage to the semiconductor layer 108 during one or more etching processes (e.g., wet etch(es)) performed on the substrate 102 after forming the semiconductor layer 108. In further embodiments, the doped cap layer 110 may act as a second contact region for the photodetector 104. In yet further embodiments, the doped cap layer 110 having the first doping type (e.g., p-type) with the relatively high doping concentration (e.g., greater than approximately 1×10¹⁹ atoms/cm³) facilitates a good electrical connection and/or facilitates reducing dark current in the photodetector 104. As a result, a performance and reliability of the photodetector 104 is increased.

The thickness 220 of the doped cap layer 110 is, for example, equal to or greater than approximately 40 nm, within a range of approximately 40 to 50 nm, or some other suitable value. In some embodiments, the thickness 220 being equal to or greater than approximately 40 nm facilitates the doped cap layer 110 being sufficiently thick to protect the semiconductor layer 108. In various embodiments, the thickness 220 being equal to or less than approximately 50 nm increases the sensing area of the photodetector 104, thereby further increasing the performance (e.g., SNR) of the photodetector 104. In some embodiments the thickness 220 of the doped cap layer 110 is equal to the thickness 216 of the interlayer 106.

In some embodiments, the doped peripheral region 112 continuously extends from the top surface 102t of the substrate 102 by a vertical distance 222 to a first point below the top surface 102t. The vertical distance 222 may correspond to a thickness or height of the doped peripheral region 112. The vertical distance 222 is, for example, equal to or greater than approximately 50 nm, within a range of approximately 50 to 90 nm, or some other suitable value. In various embodiments, the vertical distance 222 is greater than the thickness 220 of the doped cap layer 110. In some embodiments, the vertical distance 222 being greater than or equal to approximately 50 nm facilitates the doped peripheral region 112 reducing dark current in the photodetector 104. In further embodiments, the vertical distance 222 being less than or equal to approximately 90 nm reduces a duration of an annealing process utilized to form the doped peripheral region 112.

In various embodiments, the doped peripheral region 112 laterally extends from an outer sidewall of the doped cap layer 110 by a lateral distance 221 to a second point 223 in a direction away from the semiconductor layer 108. The lateral distance 221 may correspond to a width of the doped peripheral region 112 along a single side of the doped cap layer 110. The lateral distance 221 is, for example, equal to or greater than approximately 75 nm, approximately 150 nm, within a range of approximately 75 to 250 nm, or some other suitable value.

In some embodiments, the doped peripheral region 112 has a gradient doping profile, where a peak doping concentration of the doped peripheral region 112 abuts the semiconductor layer 108 and/or is arranged in the interlayer 106. In various embodiments, the doping concentration of the doped peripheral region 112 continuously decreases along the lateral distance 221 in the direction away from the semiconductor layer 108. For example, the peak doping concentration of the doped peripheral region 112 is adjacent to the doped cap layer 110 and/or the semiconductor layer 108 and a minimum doping concentration of the doped peripheral region 112 is at the second point 223. In such embodiments, the peak doping concentration of the doped peripheral region 112 is closer to the doped cap layer and/or the semiconductor layer 108 than the second point 223.

In some embodiments, the lateral distance 221 being equal to or greater than approximately 75 nm facilitates the doped peripheral region 112 reducing dark current in the photodetector 104. In further embodiments, the lateral distance 221 being equal to or less than approximately 250 nm facilitates a peak of the doping concentration of the doped peripheral region 112 being closer to interfaces between the semiconductor layer 108 and the substrate 102. In some embodiments, the doped peripheral region 112 is laterally offset from the first contact regions 206 and/or is vertically offset from the outer lateral wells 208. In further embodiments, the doped peripheral region 112 contacts at least an individual side of each of the first contact regions 206 and/or contacts a top of each of the outer lateral wells 208.

FIG. 2B illustrates a top view 200b of some embodiments of the image sensor of FIG. 2A. The cross-sectional view 200a of FIG. 2A may, for example, be taken along the line A-A′ in FIG. 2B. The top view 200b of FIG. 2B may, for example, be taken along the line A-A′ in FIG. 2A.

As illustrated in FIG. 2B, the interlayer 106 continuously laterally extends around an outer perimeter of the semiconductor layer 108. The doped peripheral region 112 continuously laterally extends around the outer perimeter of the semiconductor layer 108 and the outer perimeter of the interlayer 106. In various embodiments, the doped peripheral region 112 is ring-shaped as viewed in the top view 200b. In further embodiments, the doped peripheral region 112 contacts and/or abuts the plurality of first contact regions 206. The isolation structure 114 continuously laterally extends around the semiconductor layer 108 and is laterally offset from the interlayer 106 In some embodiments, the middle well region 204 is aligned with a middle of the semiconductor layer 108.

The plurality of outer lateral wells 208 comprise an individual outer lateral well arranged at each side of the semiconductor layer 108. In some embodiments, the semiconductor layer 108 has a rectangular shape when viewed in top view and the plurality of outer lateral wells 208 comprises an individual outer lateral well at each of the four sides of the semiconductor layer 108. It will be appreciated that the semiconductor layer 108 may have other shapes when viewed in top view. In various embodiments, the plurality of first contact regions 206 comprises an individual contact region over a corresponding outer lateral well in the plurality of outer lateral wells 208. In further embodiments, the outer lateral wells 208 are each laterally offset from a corresponding side of the middle well region 204 by a non-zero distance that may, for example, be greater than a thickness of the interlayer 106.

FIG. 2C illustrates a cross-sectional view 200c of some embodiments of a section of the image sensor of FIG. 2A. The cross-sectional view 200c of FIG. 2C may correspond to an enlarged section (taken from box 224 of FIG. 2A) of the image sensor of FIG. 2A.

In some embodiments, a height of the doped peripheral region 112 decreases from a sidewall of the doped cap layer 110 in a direction away from the doped cap layer 110. In various embodiments, an outer lateral well 208 extends along a bottom and sides of a corresponding first contact region 206. The outer lateral well 208 may continuously laterally extend from the first contact region 206 to the doped peripheral region 112, a side of the interlayer 106, and/or a side of the semiconductor layer 108. In various embodiments, a top of the outer lateral well 208 may be aligned with a top of the doped peripheral region 112 and/or a top of the first contact region 206. In further embodiments, the first contact region 206 may contact the doped peripheral region 112.

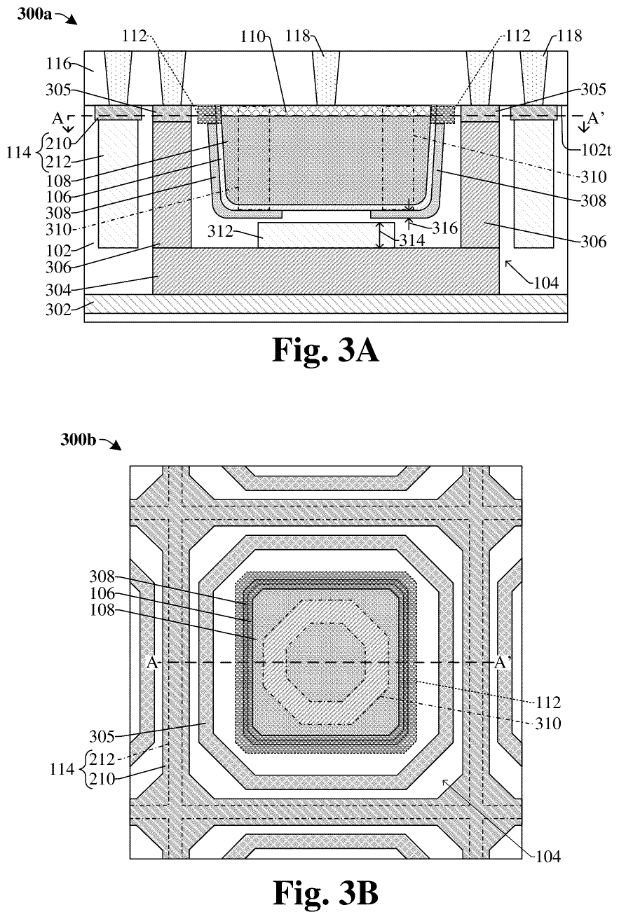

FIGS. 3A and 3B illustrate a cross-sectional view 300a and a top view 300b of some other embodiments of an image sensor comprising a doped cap layer 110 over a semiconductor layer 108 of a photodetector 104 and a doped peripheral region 112 adjacent to outer edges of the semiconductor layer 108. The image sensor of FIGS. 3A and 3B may correspond to some other embodiments of the image senor of FIG. 1, where the photodetector 104 is configured as an avalanche photodiode (APD), a single-photon avalanche diode (SPAD), or the like. The cross-sectional view 300a of FIG. 3A may, for example, be taken along the line A-A′ in FIG. 3A. The top view 300b of FIG. 3B may, for example, be taken along the line A-A′ in FIG. 3A.

In some embodiments, the photodetector 104 comprises the semiconductor layer 108, the doped cap layer 110, a first avalanche well 304, a second avalanche well 312, a vertical connection well 306, a first contact region 305, and a guard ring region 310. A bottom well 302 is disposed in the substrate 102 below the first avalanche well 304. The first avalanche well 304 underlies the semiconductor layer 108. The bottom well 302 comprises the first doping type (e.g., p-type) and the first avalanche well 304 comprises the second doping type (e.g., n-type). The first contact region 305 is disposed in the substrate 102 on opposing sides of the semiconductor layer 108 and comprises the second doping type (e.g., n-type). In some embodiments, the first contact region 305 is ring-shaped and laterally extends around the semiconductor layer 108 (e.g., as shown in FIG. 3B). The vertical connection well 306 is disposed in the substrate 102 and continuously vertically extends from the first contact region 305 to the first avalanche well 304. The vertical connection well 306 comprises the second doping type (e.g., n-type). In some embodiments, when viewed in top view the vertical connection well 306 is ring-shaped and laterally extends around the semiconductor layer 108.

The second avalanche well 312 is disposed in the substrate 102 between the semiconductor layer 108 and the first avalanche well 304. The second avalanche well 412 comprises the first doping type (e.g., p-type). In some embodiments, a thickness 314 of the second avalanche well 412 is within a range of approximately 280 to 320 nm or some other suitable value. The guard ring region 310 is arranged in the semiconductor layer 108. It will be appreciated that the guard ring region 310 is represented in phantom for ease of illustration. In some embodiments, the guard ring region 310 continuously extends from the top surface of the doped cap layer 110 through the semiconductor layer 108 to a bottom surface of the interlayer 106. In various embodiments, when viewed from top view, the guard ring region 310 is ring-shaped. The guard ring region 310 comprises the first doping type (e.g., p-type).

A doped surface region 308 is disposed in the substrate 102 along sidewalls of the interlayer 106 and a lower surface of the interlayer 106. The doped surface region 308 comprises the first doping type (e.g., p-type). In some embodiments, a thickness 316 of the doped surface region 308 along the interlayer 106 is approximately 50 nm, within a range of approximately 45 to 55 nm, or some other suitable value. In various embodiments, the doped surface region 308 is disposed below or contacts a bottom of the doped peripheral region 112. The doped surface region 308 may be configured to passivate crystalline defects (e.g., dangling bonds, lattice defects, etc.) along surfaces of the substrate 102 that define the recess the semiconductor layer 108 is disposed in. Accordingly, the doped surface region 308 may further reduce dark current in the photodetector 104. The doped peripheral region 112 is arranged in the substrate 102 on opposing sides of the semiconductor layer 108. The isolation structure 114 comprises the upper doped isolation region 210 and the lower doped isolation region 212 underlying the upper doped isolation region 210.

In some embodiments, the first contact region 305 may be configured as a cathode of the photodetector 104 and the doped cap layer 110 may be configured as an anode of the photodetector 104. Incident electromagnetic radiation that strikes the semiconductor layer 108 can cause an electron hole pair to be generated in the semiconductor layer 108. The photodetector 104 may be biased by way of the plurality of conductive contacts 118. For example, the first contact region 305 may be biased with 0 V and the doped cap layer 110 may be biased with −10 to −25 V, it will be appreciated that other bias voltages are amenable. In various embodiments, the photodetector 104 may be reverse biased bear or above its breakdown voltage. As a result, a high electric field is generated across the photodetector 104 such that released charge carriers (e.g., electrons released from the generated electron hole pair) move towards and are accelerated at an avalanche region between the first and second avalanche wells 304, 312. This triggers an avalanche current that increases an electrical signal generated by the incident electromagnetic radiation and increases detection of the incident electromagnetic radiation. The doped cap layer 110 and the doped peripheral region 112 are configured to reduce dark current in the photodetector 104, thereby increasing performance (e.g., increasing QE, SNR, etc.) of the photodetector 104.

In some embodiments, the doped surface region 308 is laterally offset from and continuously wraps around a middle region of the semiconductor layer 108. This facilitates directing charge carriers from the semiconductor layer 108 to the first and second avalanche wells 304, 312. In various embodiments, the guard ring region 310 and the doped peripheral region 112 are ring-shaped as view in top view and may each be configured to assist in redistributing the electric field in the photodetector 104, such that it is more uniform.

In some embodiments, the doping concentration of the doped cap layer 110 is greater than a doping concentration of the guard ring region 310 and/or is greater than a doping concentration of the second avalanche well 312. The doping concentration of the guard ring region 310 may, for example, be within a range of approximately 1×10¹⁶ to 1×10¹⁷ atoms/cm³ or some other suitable value. A doping concentration of the doped surface region 308 may, for example, be within a range of approximately 1×10¹⁷ to 1×10¹⁹ atoms/cm³ or some other suitable value. A doping concentration of the second avalanche well 312 may, for example, be within a range of approximately 1×10¹⁶ to 1×10¹⁸ atoms/cm³ or some other suitable value. In various embodiments, the doping concentration of the doped peripheral region 112 is greater than the doping concentration of the guard ring region 310, the doping concentration of the doped surface region 308, and/or the doping concentration of the second avalanche well 312.

In some embodiments, a doping concentration of the first contact region 305 is greater than a doping concentration of the vertical connection well 306 and/or is greater than a doping concentration of the first avalanche well 304. The doping concentration of the first contact region 305 may, for example, be within a range of approximately 1×10¹⁷ to 1×10²⁰ atoms/cm³ or some other suitable value. The doping concentration of the first avalanche well 304 may, for example, be within a range of approximately 1×10¹⁶ to 1×10¹⁸ atoms/cm³ or some other suitable value. The doping concentration of the vertical connection well 306 may, for example, be within a range of approximately 1×10¹⁶ to 1×10¹⁸ atoms/cm³ or some other suitable value. In various embodiments, the doping concentration of the doped peripheral region 112 is greater than the doping concentration of the first avalanche well 304 and/or is greater than the doping concentration of the vertical connection well 306. In further embodiments, the doped peripheral region 112 contacts or abuts sides of the first contact region 305 and/or sides of the vertical connection well 306.

As illustrated in the top view 300b of FIG. 3B, in some embodiments, the interlayer 106 extends around the outer perimeter of the semiconductor layer 108. The doped peripheral region 112 is ring-shaped and extends around the outer perimeters of the semiconductor layer 108.

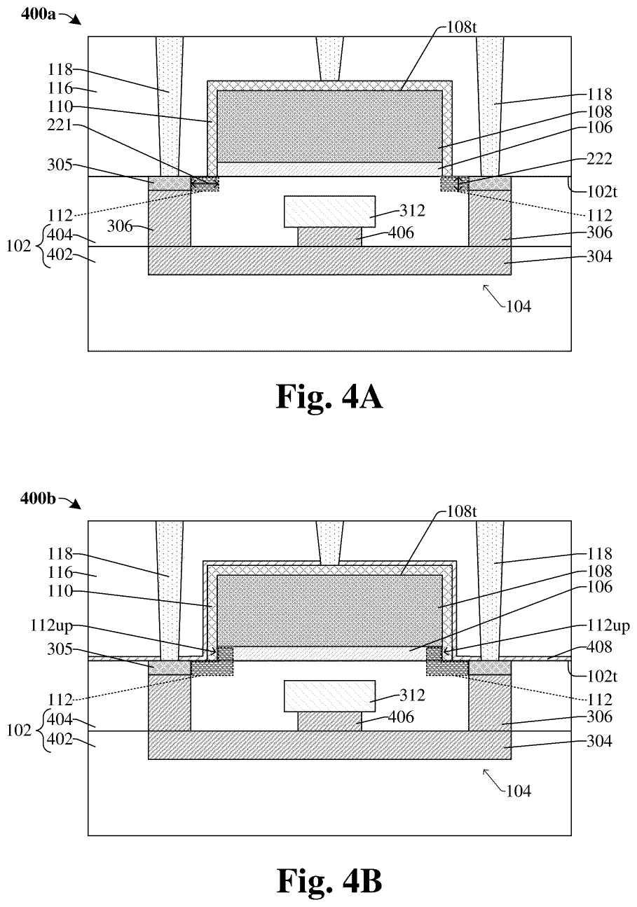

FIG. 4A illustrate a cross-sectional view 400a of some other embodiments of an image sensor comprising a doped cap layer 110 over a semiconductor layer 108 of a photodetector 104 and a doped peripheral region 112 adjacent to outer edges of the semiconductor layer 108. The image sensor of FIG. 4A may correspond to some other embodiments of the image sensor of FIGS. 3A and 3B, where the semiconductor layer 108 is arranged above the top surface 102t of the substrate 102.

In some embodiments, the substrate 102 comprises a base substrate 402 and an upper substrate layer 404 over the base substrate 402. The base substrate 402 may, for example, be or comprise silicon, monocrystalline silicon, or some other semiconductor material. The upper substrate layer 404 may, for example, be or comprise silicon, epitaxial silicon, or some other suitable semiconductor material. In some embodiments, a thickness of the upper substrate layer 404 is less than a thickness of the base substrate 402. A bulk of the base substrate 402 and/or a bulk of the upper substrate layer 404 may comprise the first doping type (e.g., p-type).

In some embodiments, the photodetector 104 comprises the semiconductor layer 108, the first avalanche well 304, the second avalanche well 312, an avalanche well extension region 406, the vertical connection well 306, the doped cap layer 110, and the first contact region 305. The first avalanche well 304 is arranged in the base substrate 402. The vertical connection well 306 is arranged in the upper substrate layer 404 over the first avalanche well 304. The first contact region 305 is arranged in the upper substrate layer 404 and overlies the vertical connection well 306. The second avalanche well 312 is arranged in the upper substrate layer 404 and overlies the first avalanche well 304.

The avalanche well extension region 406 is arranged between the first avalanche well 304 and the second avalanche well 312. In some embodiments, the first contact region 305 and the vertical connection well 306 are each ring-shaped when viewed from above and extend around the second avalanche well 312. The avalanche well extension region 406 has the second doping type (e.g., n-type). In some embodiments, a width of the avalanche well extension region 406 is less than a width of the second avalanche well 412. The avalanche well extension region 406 is configured to enhance and/or better confine released charge carriers at the avalanche region between the first and second avalanche wells 304, 312.

The semiconductor layer 108 overlies the substrate 102. The interlayer 106 is arranged between the top surface 102t of the substrate 102 and the semiconductor layer 108. The top surface 102t of the substrate 102 may be defined by a top surface of the upper substrate layer 404. In some embodiments, a bottom surface of the semiconductor layer 108 is vertically offset the top surface 102t of the substrate 102 by a vertical distance that is non-zero and may, for example, be equal to a thickness of the interlayer 106. The vertical distance may, for example, be within a range of approximately 40 to 50 nm or some other suitable value. In some embodiments, outer sidewalls of the semiconductor layer 108 are aligned with outer sidewalls of the interlayer 106.

In some embodiments, the doped cap layer 110 directly contacts a top surface 108t and the outer sidewalls of the semiconductor layer 108. Further, the doped cap layer 110 may directly contact the outer sidewalls of the interlayer 106. In various embodiments, a bottom surface of the doped cap layer 110 is aligned with a bottom surface of the interlayer 106. Further, the bottom surface of the doped cap layer 110 may directly contact the top surface 102t of the substrate 102. The doped cap layer 110 continuously wraps around and contacts an outer perimeter of the semiconductor layer 108. By virtue of the doped cap layer 110 being disposed on the top surface 108t and the outer sidewalls of the semiconductor layer 108, damage to the semiconductor layer 108 may be reduced.

The doped peripheral region 112 is arranged in the upper substrate layer 404 and directly underlies the bottom surface of the doped cap layer 110. In various embodiments, the doped peripheral region 112 extends laterally from under the outer opposing sidewalls of the semiconductor layer 108 to the first contact region 305 and/or the vertical connection well 306. The dielectric structure 116 overlies and laterally encloses the semiconductor layer 108. The plurality of conductive contacts 118 are arranged in the dielectric structure 116. Disposing the semiconductor layer 108 over the top surface 102t of the substrate 102 may, for example, mitigate defects between the outer sidewalls of the semiconductor layer 108 and the substrate 102. In addition, the semiconductor layer 108 overlying the top surface 102t mitigates leakage current at outer regions of the semiconductor layer 108 and enhances optical and/or electrical isolation between the photodetector 104 and other photodetectors (not shown) over and/or in the substrate 102. Further, the doped peripheral region 112 underlying the semiconductor layer 108 reduces dark current in the photodetector 104 and enhances an electric field in an active region (e.g., a region aligned with the second avalanche well 312) of the photodetector 104.

FIG. 4B illustrates a cross-sectional view 400b of some other embodiments of the image senor of FIG. 4A, where the doped peripheral region 112 comprises an upper protrusion 112up arranged in the interlayer 106.

In some embodiments, the upper protrusion 112up of the doped peripheral region 112 directly contacts the bottom surface of the semiconductor layer 108. The doped peripheral region 112 continuously extends from an inner sidewall of the doped cap layer 110 to the bottom surface of the doped cap layer 110. In various embodiments, the doped peripheral region 112 comprises an L-shaped segment adjacent to each sidewall in the outer sidewalls of the semiconductor layer 108. In some embodiments, a first width of the doped peripheral region 112 in the interlayer 106 is less than a second width of the doped peripheral region 112 in the substrate 102. In various embodiments, the doped peripheral region 112 being arranged at least in part in the interlayer 106 increase an ability for the doped peripheral region 112 to enhance the electric field in the active region of the photodetector 104 and further reduce dark current in the photodetector 104.

Further, an etch stop layer 408 is arranged over the doped cap layer 110 and the substrate 102. The etch stop layer 408 may, for example, be or comprise silicon nitride, silicon carbide, silicon oxynitride, silicon oxycarbide, some other dielectric material, or any combination of the foregoing. The etch stop layer 408 contacts a top surface and outer sidewalls of the doped cap layer 110. Further, the etch stop layer 408 extends along the top surface 102t of the substrate. In some embodiments, a bottom surface of the etch stop layer 408 is aligned with the bottom surface of the doped cap layer 110. In various embodiments, the etch stop layer 408 contacts the doped peripheral region 112.

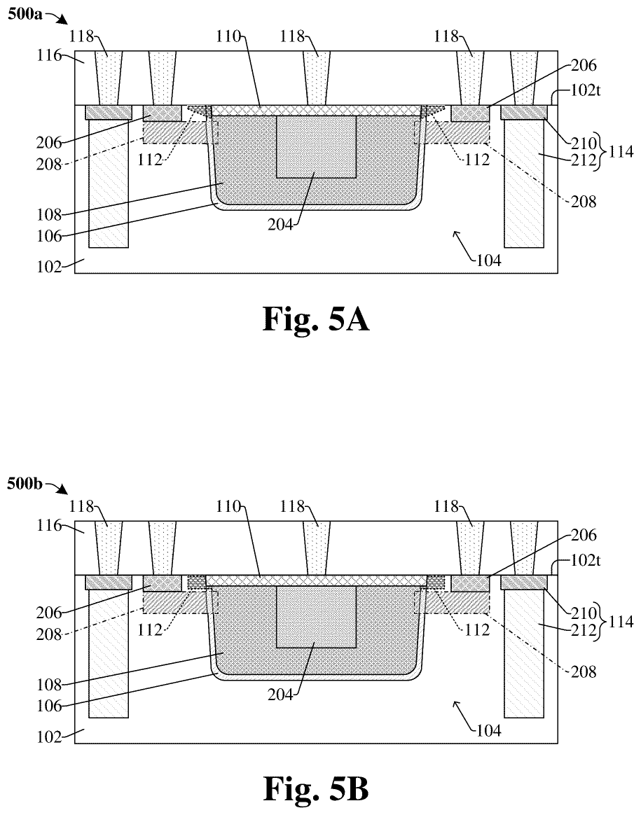

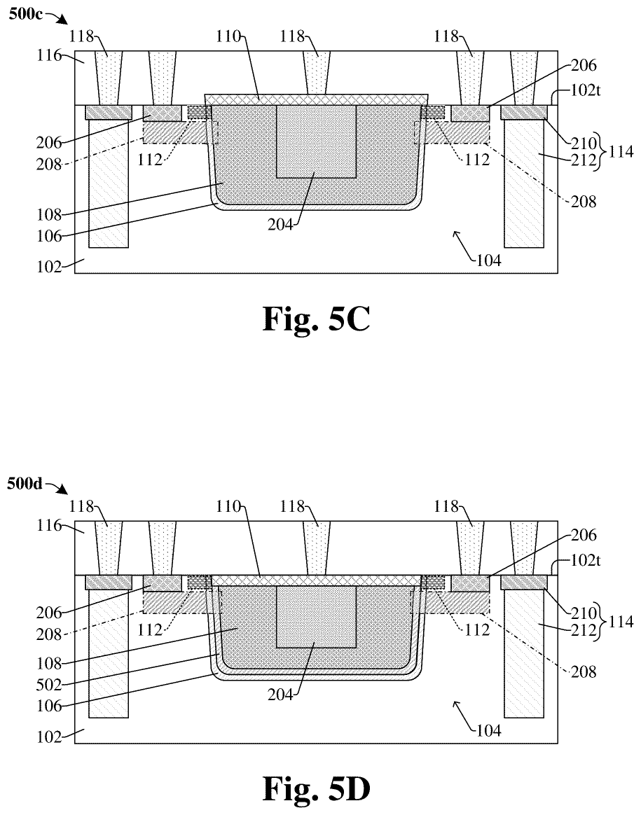

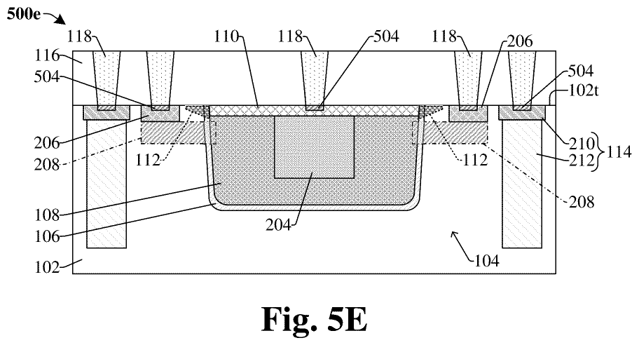

FIGS. 5A through 5E illustrate various cross-sectional views 500a-500e of some other embodiments of the image sensor of FIG. 2A.

With reference to the cross-sectional view 500a of FIG. 5A, in some embodiments, a height of the doped peripheral region 112 decreases from a sidewall of the doped cap layer 110 in a direction away from the semiconductor layer 108.

With reference to the cross-sectional view 500b of FIG. 5B, in some embodiments, a top surface of the interlayer 106 is recessed below the top surface of the substrate 102 and the doped cap layer 110 directly contacts the top surface of the interlayer 106. In various embodiments, the doped peripheral region 112 underlies and/or contacts outer segments of the bottom surface of the doped cap layer 110.

With reference to the cross-sectional view 500c of FIG. 5C, in some embodiments the top surface of the semiconductor layer 108 and the top surface of the interlayer 106 are aligned with one another and/or the top surface 102t of the substrate 102. In various embodiments, the doped cap layer 110 continuously extends along the top surface of the semiconductor layer 108 and the top surface of the interlayer 106.

With reference to the cross-sectional view 500d of FIG. 5D, in some embodiments, a buffer layer 502 is arranged between the semiconductor layer 108 and the substrate 102. In various embodiments, the buffer layer 502 comprises a compound of the first material (e.g., silicon) and the second material (e.g., germanium). The buffer layer 502 is configured to provide a good foundation to grow the semiconductor layer 108, such that a crystalline quality of the semiconductor layer 108 is improved and/or defects between the substrate 102 and the semiconductor layer 108 are reduced.

With reference to the cross-sectional view 500e of FIG. 5E, in some embodiments, a plurality of silicide layers 504 are arranged in the substrate 102 and/or the doped cap layer 110. The plurality of silicide layers 504 are disposed below the plurality of conductive contacts 118 and facilitate forming a good electrical connection (e.g., an ohmic contact) with the plurality of conductive contacts 118 and underlying doped regions and/or layers. The silicide layers 504 may, for example, be or comprise titanium silicide, cobalt silicide, nickel silicide, or the like.

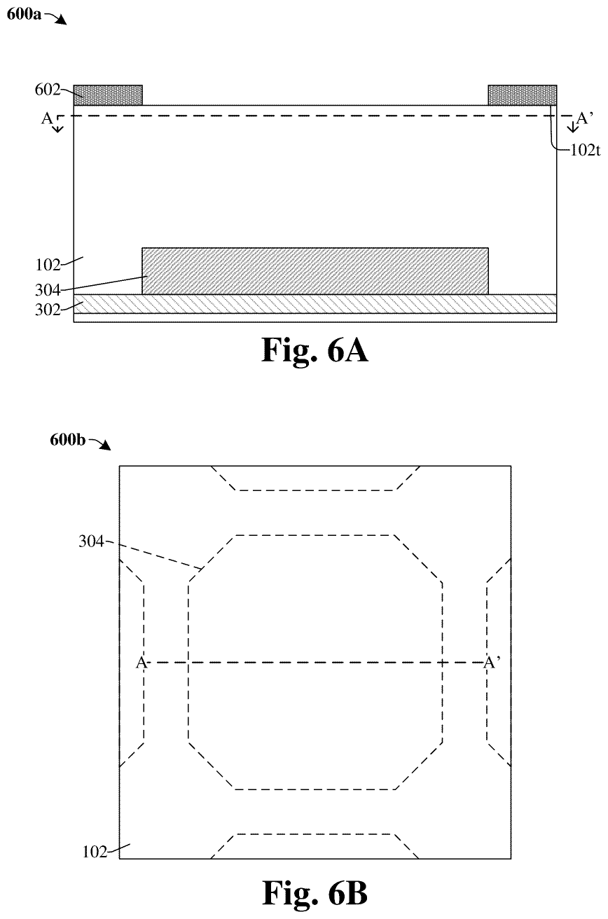

FIGS. 6A and 6B through 19A and 19B illustrate a series of various views of some embodiments of a method for forming an image sensor comprising a doped cap layer over a semiconductor layer of a photodetector and a doped peripheral region adjacent to outer edges of the semiconductor layer. Figures with a suffix of “A” illustrate a cross-sectional view of the image sensor during various formation processes. Figures with a suffix of “B” illustrate a top view taken along the line A-A′ of Figures with a suffix of “A.”

Although the various views shown in FIGS. 6A and 6B through 19A and 19B are described with reference to a method of forming the image sensor, it will be appreciated that the structures shown in FIGS. 6A and 6B through 19A and 19B are not limited to the method of formation but rather may stand alone separate of the method. Further, although FIGS. 6A and 6B through 19A and 19B are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in cross-sectional view 600a and top view 600b of FIGS. 6A and 6B, a substrate 102 is provided and a bottom well 302 and a first avalanche well 304 are formed in the substrate 102. The substrate 102 comprises a first material and may be doped with a first doping type (e.g., p-type). In some embodiments, the first material is or comprises silicon or some other semiconductor material(s). In some embodiments, forming the bottom well 302 includes performing an ion implantation process that implants one or more first dopants (e.g., boron, gallium, indium, or the like) having the first doping type (e.g., p-type) into the substrate. The ion implantation process utilized to formed the bottom well 302 may, for example, be or comprise a blanket implantation process. In some embodiments, forming the first avalanche well 304 includes: forming a first implant mask 602 over the substrate 102; performing an ion implantation process that implants one or more second dopants (e.g., phosphorus, arsenic, antimony, or the like) having a second doping type (e.g., n-type) into the substrate 102 with the first implant mask 602 in place; and removing the first implant mask 602.

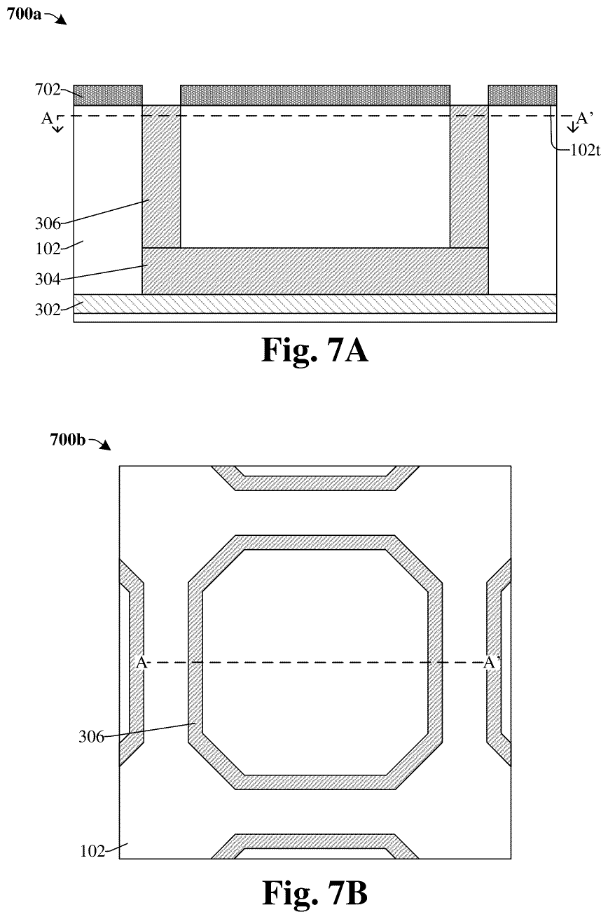

As shown in cross-sectional view 700a and top view 700b of FIGS. 7A and 7B, a vertical connection well 306 is formed in the substrate 102 over the first avalanche well 304. In some embodiments, forming the vertical connection well 306 includes: forming a second implant mask 702 over the substrate 102; performing an ion implantation process that implants one or more second dopants (e.g., phosphorus, arsenic, antimony, or the like) having the second doping type (e.g., n-type) into the substrate 102 with the second implant mask 702 in place; and removing the second implant mask 702.

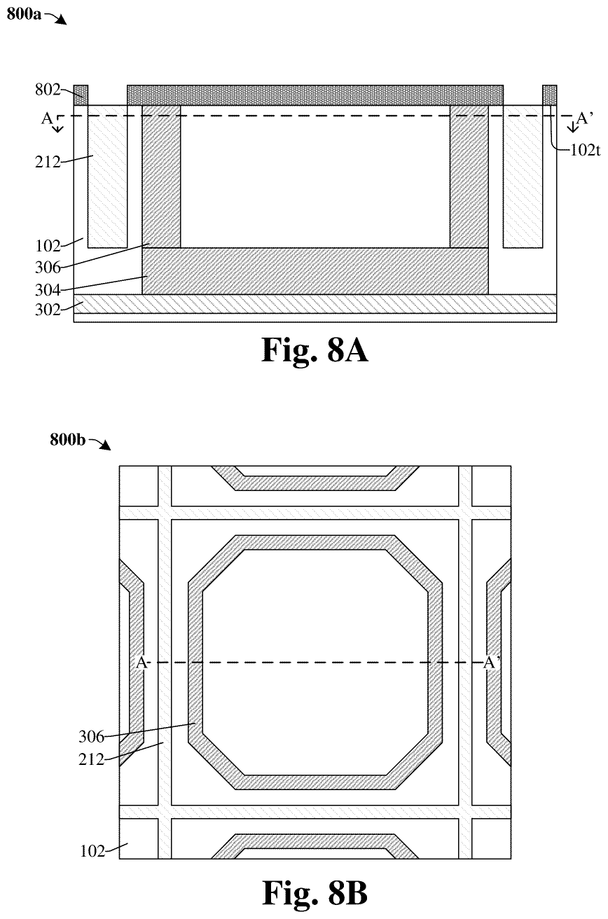

As shown in cross-sectional view 800a and top view 800b of FIGS. 8A and 8B, a lower doped isolation region 212 is formed in the substrate 102. The lower doped isolation region 212 continuously extends around the vertical connection well 306. In some embodiments, forming the lower doped isolation region 212 includes: forming a third implant mask 802 over the substrate 102; performing an ion implantation process that implants one or more first dopants (e.g., boron, gallium, indium, or the like) having the first doping type (e.g., p-type) into the substrate 102 with the third implant mask 802 in place; and removing the third implant mask 802.

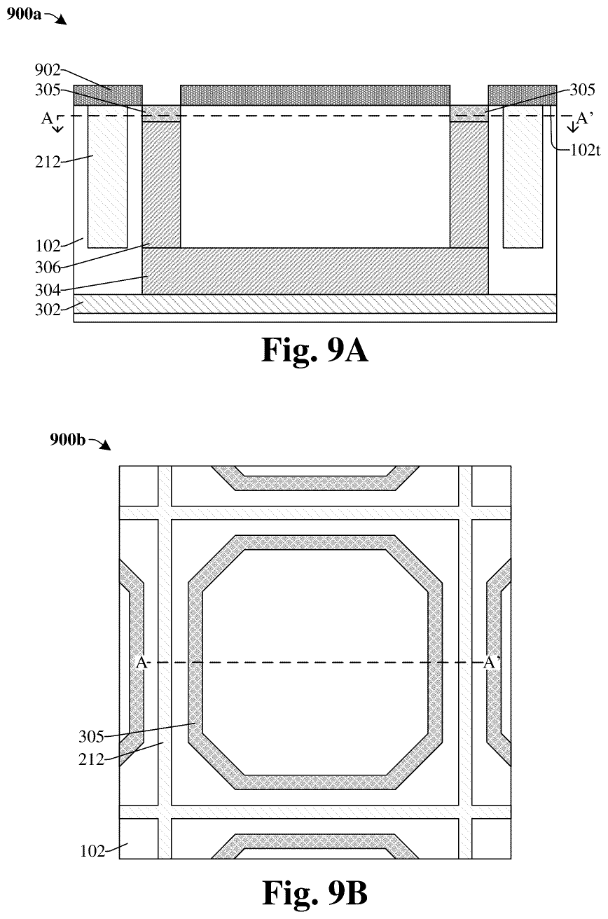

As shown in cross-sectional view 900a and top view 900b of FIGS. 9A and 9B, a first contact region 305 is formed in the substrate 102 over the vertical connection well 306. In some embodiments, forming the first contact region 305 includes: forming a fourth implant mask 902 over the substrate 102; performing an ion implantation process that implants one or more second dopants (e.g., phosphorus, arsenic, antimony, or the like) having the second doping type (e.g., n-type) into the substrate 102 with the fourth implant mask 902 in place; and removing the fourth implant mask 902.

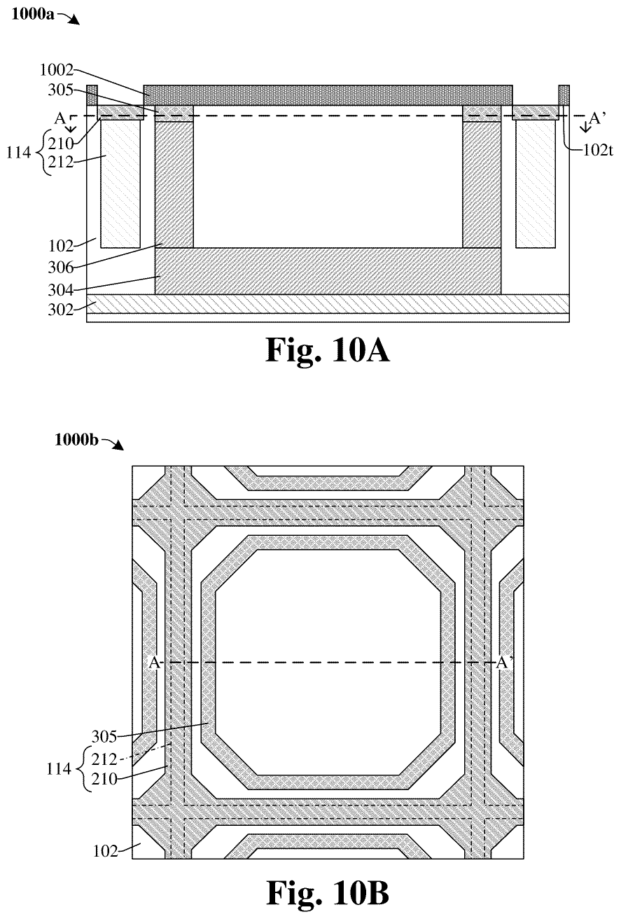

As shown in cross-sectional view 1000a and top view 1000b of FIGS. 10A and 10B, an upper doped isolation region 210 is formed in the substrate 102 over the lower doped isolation region 212, thereby forming or defining an isolation structure 114. In some embodiments, forming the upper doped isolation region 210 includes: forming a fifth implant mask 1002 over the substrate 102; performing an ion implantation process that implants one or more first dopants (e.g., boron, gallium, indium, or the like) having the first doping type (e.g., p-type) into the substrate 102 with the fifth implant mask 1002 in place; and removing the fifth implant mask 1002.

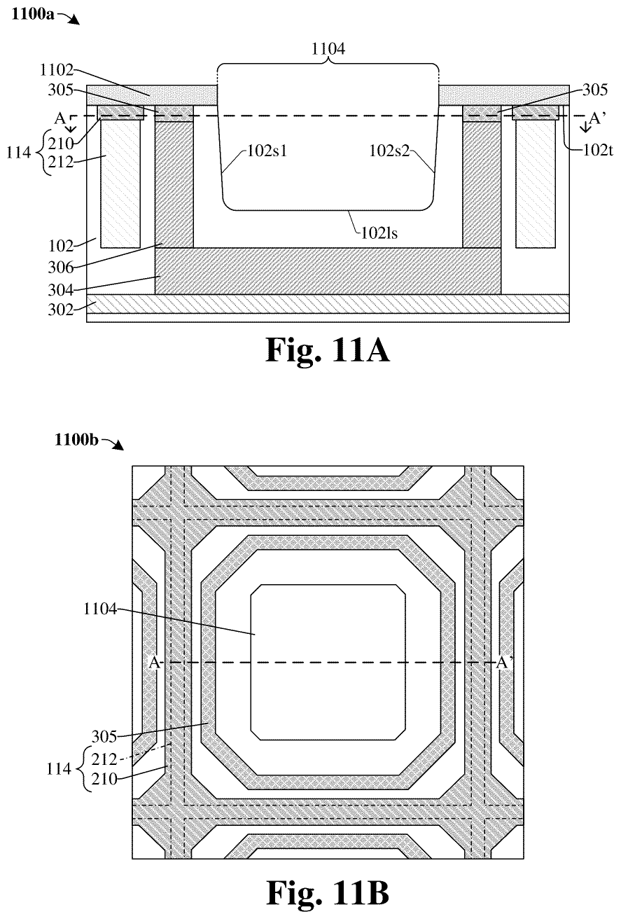

As shown in cross-sectional view 1100a and top view 1100b of FIGS. 11A and 11B, a patterning process is performed on the substrate 102 to form a recess 1104 in the substrate 102. The recess 1104 is defined at least in part by opposing sidewalls 102s1, 102s2 and a lower surface 102ls of the substrate 102. In some embodiments, the patterning process includes forming a masking layer 1102 over the substrate 102 and performing an etching process on the substrate 102 with the masking layer 1102 in place. In some embodiments, the etching process includes a dry etch (e.g., a reactive-ion etch, a plasma etch, or the like) or some other suitable etch process. In various embodiments, the masking layer 1102 may be removed after the etching process.

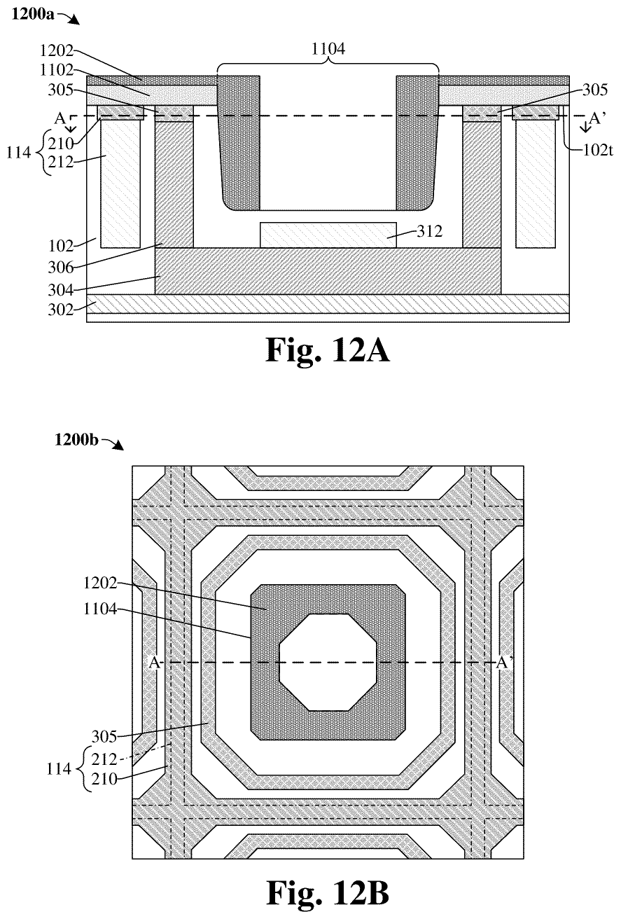

As shown in cross-sectional view 1200a and top view 1200b of FIGS. 12A and 12B, a second avalanche well 312 is formed in the substrate 102 over the first avalanche well 304. In some embodiments, forming the second avalanche well 312 includes: forming a sixth implant mask 1202 over the substrate 102; performing an ion implantation process to implant one or more first dopants (e.g., boron, gallium, indium, or the like) having the first doping type (e.g., p-type) into the substrate 102 with the sixth implant mask 1202 in place; and removing the sixth implant mask 1202.

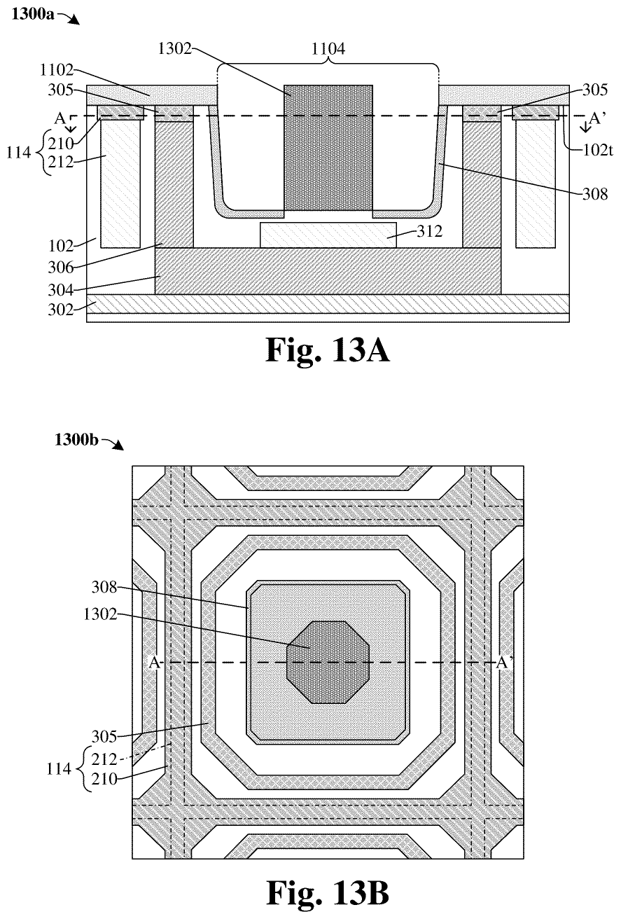

As shown in cross-sectional view 1300a and top view 1300b of FIGS. 13A and 13B, a doped surface region 308 is formed in the substrate 102. In some embodiments, forming the doped surface region 308 includes: forming a seventh implant mask 1302 over the substrate 102; performing an ion implantation process to implant one or more first dopants (e.g., boron, gallium, indium, or the like) having the first doping type (e.g., p-type) into the substrate 102 with the seventh implant mask 1302 in place; and removing the seventh implant mask 1302.

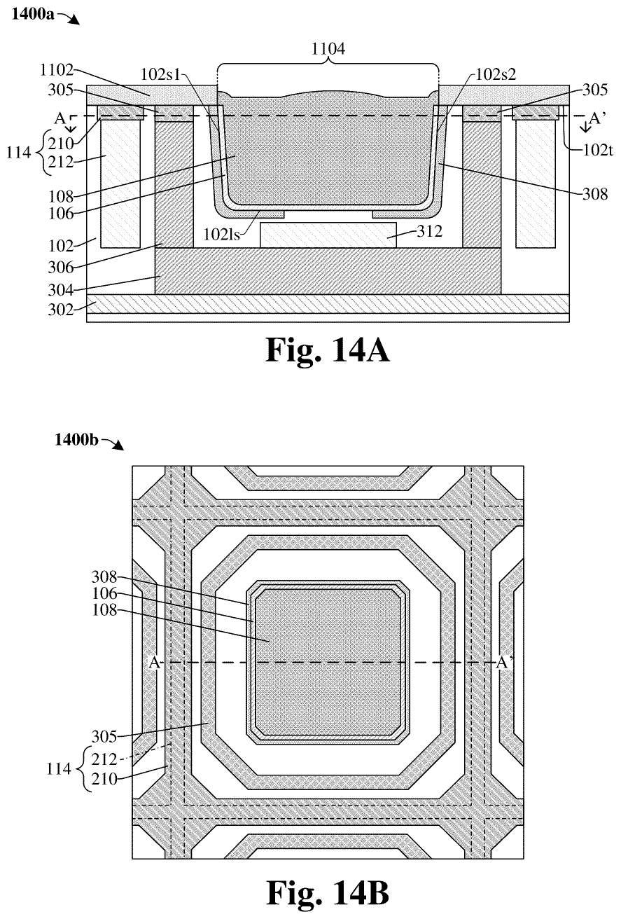

As shown in cross-sectional view 1400a and top view 1400b of FIGS. 14A and 14B, an interlayer 106 is formed lining the recess 1104 and a semiconductor layer 108 is formed over the interlayer 106 filling the recess 1104. The interlayer 106 is formed along the opposing sidewalls 102s1, 102s2 and the lower surface 102ls of the substrate 102. In some embodiments, the interlayer 106 comprises the first material (e.g., silicon) and is undoped. In some embodiments, the semiconductor layer 108 comprises a second material (e.g., germanium) different from the first material.

In some embodiments, the interlayer 106 is formed by a first epitaxial process that selectively grows the interlayer 106 along the opposing sidewalls 102s1, 102s2 and the lower surface 102ls of the substrate 102. The first epitaxial process may, for example, be or comprise molecular-beam epitaxy (MBE), chemical vapor deposition (CVD), vapor-phase epitaxy (VPE), liquid-phase epitaxy (LPE), or some other suitable deposition or growth process. In some embodiments, the semiconductor layer 108 is formed by a second epitaxial process that selectively grows the semiconductor layer 108 along surfaces of the interlayer 106 in the recess 1104. The second epitaxial process may, for example, be or comprise MBE, CVD, VPE, LPE, or some other suitable deposition or growth process. In various embodiments, the semiconductor layer 108 comprises the first doping type (e.g., p-type). In such embodiments, the semiconductor layer 108 may be in-situ doped with one or more first dopants (e.g., boron, gallium, indium, or the like) during the second epitaxial process.

As shown in cross-sectional view 1500a and top view 1500b of FIGS. 15A and 15B, a top surface of the semiconductor layer 108 is planarized and/or recessed below the top surface 102t of the substrate 102. In various embodiments, the planarization flattens the top surface of the semiconductor layer 108 and the recessing recesses the top surface of the semiconductor layer 108 below the top surface 102t of the substrate 102. In some embodiments, the top surface of the semiconductor layer 108 is not recessed and may, for example, be aligned with the top surface 102t of the substrate 102. In yet further embodiments, the planarization may remove the masking layer 1102. The top surface of the semiconductor layer 108 is planarized by, for example, a chemical mechanical polish (CMP) process or some other suitable planarization process. The top surface of the semiconductor layer 108 is recessed by, for example, an etch back or some other suitable recessing process.

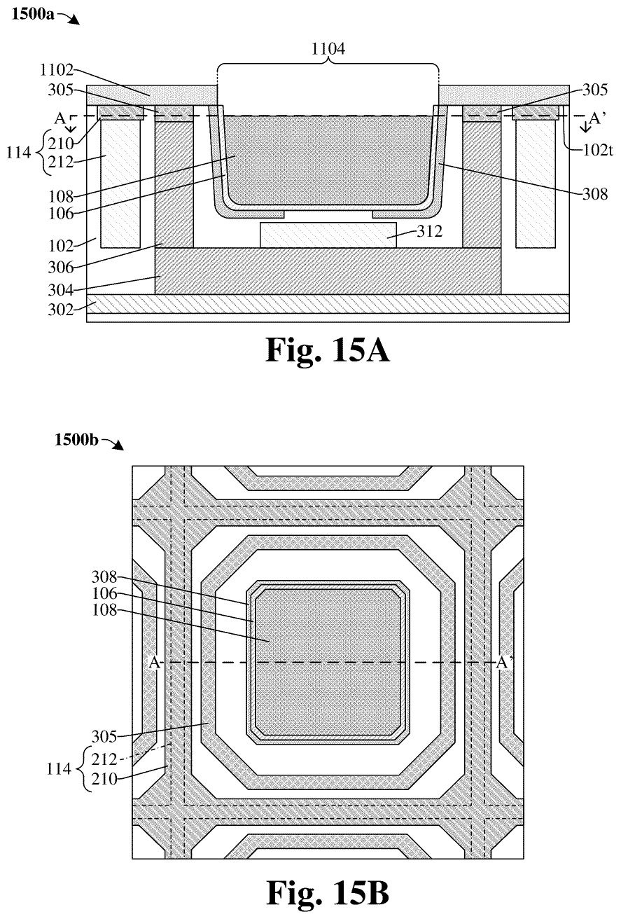

As shown in cross-sectional view 1600a and top view 1600b of FIGS. 16A and 16B, a doped cap layer 110 is formed on the semiconductor layer 108. In some embodiments, the doped cap layer 110 is part of a photodetector 104, where a process for forming the photodetector 104 includes the acts illustrated and/or described in FIGS. 6A and 6B through 17A and 17B. The doped cap layer 110 is formed by an epitaxial process that may, for example, include MBE, CVD, VPE, LPE, or some other suitable deposition or growth process. In various embodiments, the doped cap layer 110 may be formed with the masking layer (1102 of FIG. 14A) in place, such that the doped cap layer 110 grows on the semiconductor layer 108 but not on the masking layer (1102 of FIG. 14A). In such embodiments, the masking layer (1102 of FIG. 14A) is removed after forming the doped cap layer 110. In some embodiments, the doped cap layer 110 comprises the first material (e.g., silicon) and is configured to protect the semiconductor layer 108 from subsequent processing steps (e.g., subsequent wet etches). Further, the doped cap layer 110 comprises the first doping type (e.g., p-type) and may be formed with a doping concentration that is, for example, within a range of approximately 1×10¹⁹ to 1×10²² atoms/cm³ or some other suitable value. The doped cap layer 110 is formed to a thickness 220 that is, for example, within a range of approximately 40 to 50 nm or some other suitable value. In various embodiments, a planarization process (e.g., a CMP process, etch process, etc.) is performed on the doped cap layer 110.

In various embodiments, the epitaxial process utilized to form the doped cap layer 110 includes performing a CVD process (or some other suitable growth or deposition process) with: a precursor gas (e.g., saline (SiH₄) or the like) and/or a carrier gas (e.g., hydrogen (H₂) or the like); a dopant precursor gas (e.g., diaborane (B₂H₆) or the like); a temperature within a range of approximately 500 to 900 degrees Celsius or some other suitable value; and a pressure within a range of approximately 1 to 100 torr or some other suitable value. The doped cap layer 110 being formed with the dopant precursor gas (e.g., diaborane (B₂H₆) or the like) facilitates the doped cap layer 110 being in-situ doped with one or more first dopants (e.g., boron, gallium, indium, etc.) having the first doping type (e.g., p-type). In various embodiments, the doped cap layer 110 is formed such that the doping concentration of the doped cap layer 110 has a gaussian doping profile, a gradient doping profile, a uniform doping profile, or the like across the thickness 220. In an embodiment in which the doped cap layer 110 has the gradient doping profile, the doping concentration of the doped cap layer 110 may continuously increase from a top surface of the doped cap layer 110 to a bottom surface of the doped cap layer 110. In such embodiments, a flow of the dopant precursor gas may start at a peak value and gradually decrease during the epitaxial process. In another embodiment in which the doped cap layer 110 has the gaussian doping profile, a peak of the doping concentration of the doped cap layer 110 may be at or below a middle of the thickness 220 of the doped cap layer 110.

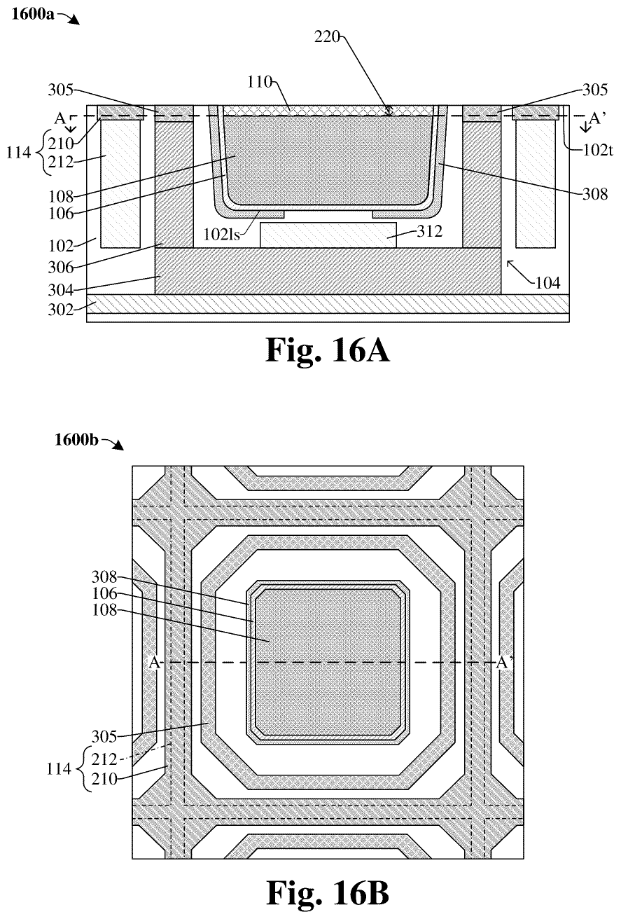

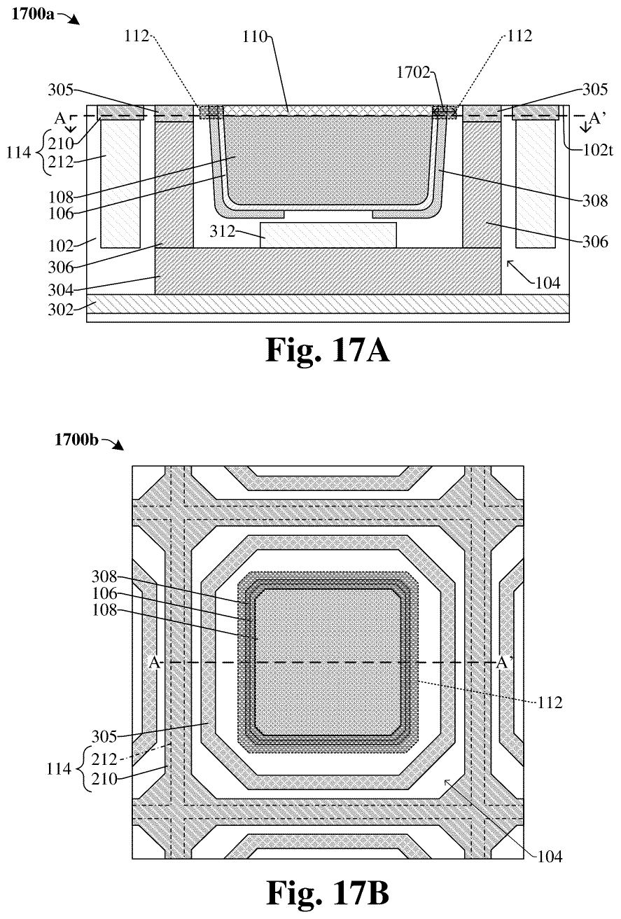

As shown in cross-sectional view 1700a and top view 1700b of FIGS. 17A and 17B, a doped peripheral region 112 is formed in the substrate 102. In some embodiments, the doped peripheral region 112 is formed at interfaces between the doped cap layer 110, the semiconductor layer 108, the interlayer 106, and the substrate 102. In various embodiments, the doped peripheral region 112 is formed by an annealing process with: a temperature within a range of approximately 700 to 900 degrees Celsius or some other suitable value; and a duration of less than or equal to 60 seconds or some other suitable value. Thus, in some embodiments, the doped peripheral region 112 is formed without an implant mask and/or without an ion implantation process. During the annealing process, the one or more first dopants of the doped cap layer 110 are driven into surrounding layers and/or structures (e.g., such as the interlayer 106 and/or the substrate 102). As a result, the doped peripheral region 112 is accurately aligned with the interfaces between the doped cap layer 110, the semiconductor layer 108, the interlayer 106, and/or the substrate 102. Thus, the doped peripheral region 112 may effectively reduce dark current in the photodetector 104. In some embodiments, a diffusion coefficient of the one or more first dopants (e.g., boron) in the first material is greater than a diffusion coefficient of the one or more first dopants in the second material. In various embodiments, by virtue of the temperature and/or duration of the annealing process and materials of the doped cap layer 110, the interlayer 106, the substrate 102, and the semiconductor layer 108, the one or more first dopants of the doped cap layer 110 more easily diffuse into the substrate 102 and/or the interlayer 106, such that the doped peripheral region 112 may be accurately aligned at the interfaces between the semiconductor layer 108 and the substrate 102.

A doping concentration of the doped peripheral region 112 may, for example, be equal to or greater than approximately 1×10¹⁶ atoms/cm³, within a range of approximately 1×10¹⁶ to 1×10²⁰ atoms/cm³, or some other suitable value. In some embodiments, the doping concentration of the doped peripheral region 112 is less than the doping concentration of the doped cap layer 110. Further, by virtue of the doped peripheral region 112 being formed by the annealing process instead of some other process (e.g., ion implantation process with an implant mask), a peak doping concentration of the doped peripheral region 112 may be closer to the interfaces between the semiconductor layer 108 and the substrate 102, thereby further increasing an ability for the doped peripheral region 112 to decrease dark current in the photodetector 104. For example, the doped peripheral region 112 may have a gradient doping profile, where the peak doping concentration of the doped peripheral region 112 abuts the semiconductor layer 108 and/or is arranged in the interlayer 106. In various embodiments, the doping concentration of the doped peripheral region 112 continuously decreases along a width 1702 of the doped peripheral region 112 in a direction away from the semiconductor layer 108. For example, the peak doping concentration of the doped peripheral region 112 is adjacent to the doped cap layer 110 and/or the semiconductor layer 108 and a minimum doping concentration of the doped peripheral region 112 is at an outer edge of the doped peripheral region 112 adjacent to the first contact region 305. In various embodiments, the doped peripheral region 112 and the doped cap layer 110 may both have a gradient doping profile.

In various embodiments, doped regions of the photodetector 104, such as the first contact region 305, the vertical connection well 306, the first avalanche well 304, and/or the second avalanche well 312, may each be formed by one or more ion implantation processes. As a result, these doped regions of the photodetector 104 may have a gaussian doping profile (e.g., the doping concentration has a bell-curve shape along a depth of the corresponding region). In various embodiments, the doped peripheral region 112 being formed by the annealing process may facilitate the doped peripheral region 112 having the gradient doping profile that is different from the gaussian doping profile. It will be appreciated that the doped peripheral region 112 having a gaussian doping profile or some other doping profile is within the scope of the present disclosure. In various embodiments, if the doped peripheral region 112 has a gaussian doping profile across the width 1702, then a peak of the doping concentration (e.g., a peak of a bell-curve shape of the doping concentration of the doped peripheral region 112) is closer to a corresponding side of the semiconductor layer 108 than an outermost edge of the doped peripheral region 112 next to the side of the semiconductor layer 108.

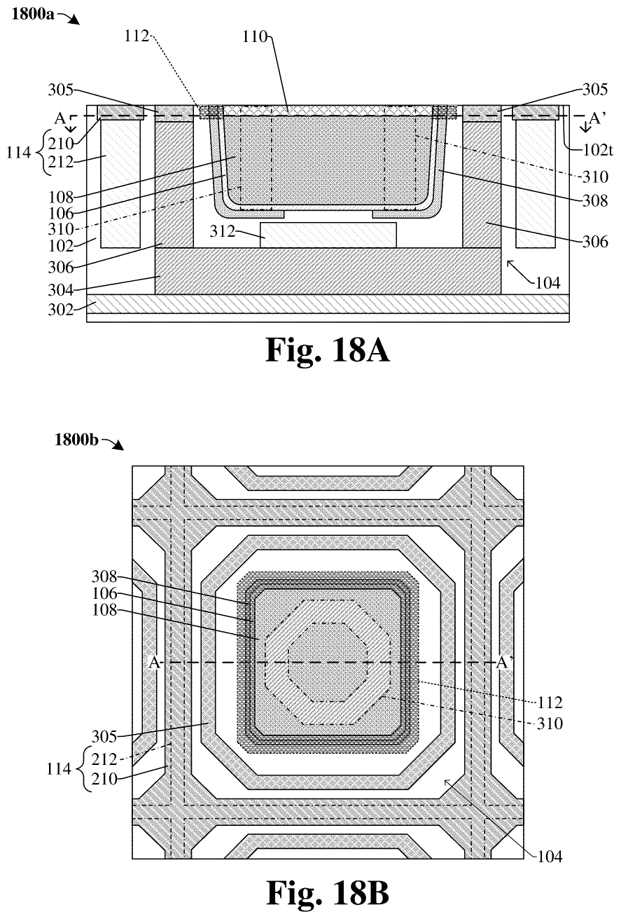

As shown in cross-sectional view 1800a and top view 1800b of FIGS. 18A and 18B, a guard ring region 310 is formed in the semiconductor layer 108. In some embodiments, the guard ring region 310 continuously vertically extends from the doped cap layer 110, through the semiconductor layer 108, to the interlayer 106. In various embodiments, forming the guard ring region 310 includes: forming an implant mask over the substrate 102; performing an ion implantation process to implant one or more first dopants (e.g., boron, gallium, indium, or the like) having the first doping type (e.g., p-type) into the semiconductor layer 108 with the implant mask in place; and removing the implant mask.

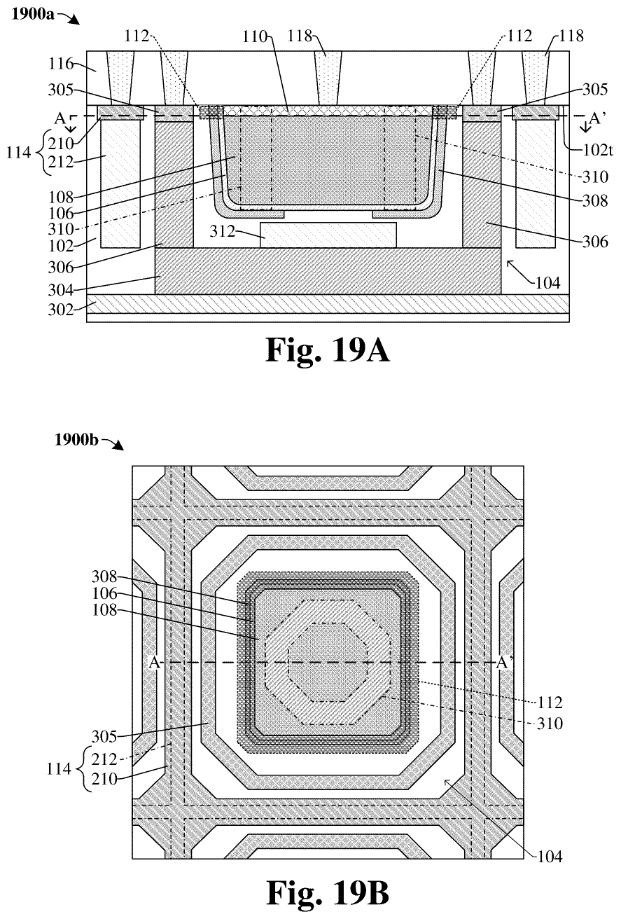

As shown in cross-sectional view 1900a and top view 1900b of FIGS. 19A and 19B, a dielectric structure 116 and a plurality of conductive contacts 118 are formed over the substrate 102. The dielectric structure 116 may, for example, be formed by a CVD process, a physical vapor deposition (PVD) process, an atomic layer deposition (ALD) process, or some other suitable growth or deposition process. The plurality of conductive contacts 118 are formed in the dielectric structure 116. The plurality of conductive contacts 118 may, for example, be formed by etching (e.g., a dry etch) the dielectric structure 116 to form a plurality of openings over the substrate 102, depositing (e.g., by CVD, PVD, sputtering, etc.) one or more conductive materials (e.g., tungsten, aluminum, copper, titanium nitride, tantalum nitride, etc.) in the plurality of openings, and performing a planarization (e.g., a CMP process) on the one or more conductive materials.

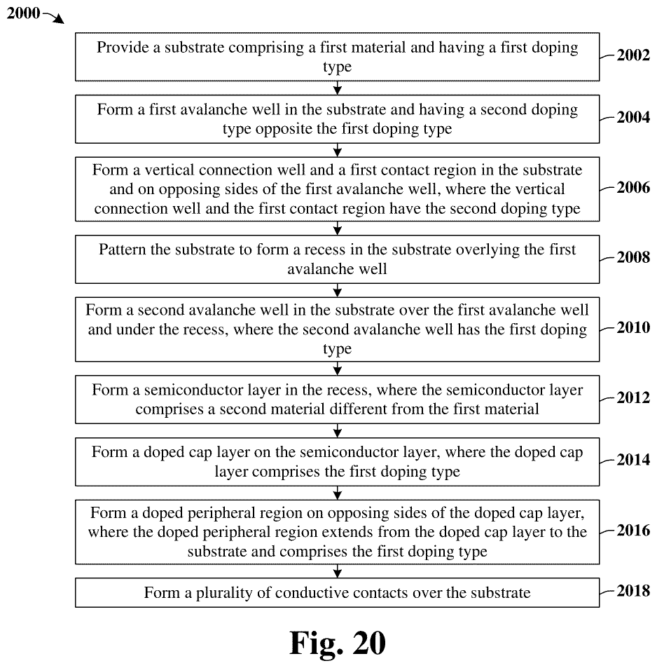

FIG. 20 illustrates a block diagram 2000 of some embodiments of the method of FIGS. 6A and 6B through 19A and 19B. Although the block diagram 2000 is illustrated and/or described as a series of acts or events, it will be appreciated that the illustrated ordering of such acts or events is not to be interpreted in a limiting sense. For example, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 2002, a substrate is provided, where the substrate comprises a first material and has a first doping type. FIGS. 6A and 6B illustrate various views corresponding to some embodiments of act 2002.

At act 2004, a first avalanche well is formed in the substrate. The first avalanche well has a second doping type opposite the first doping type. FIGS. 6A and 6B illustrate various views corresponding to some embodiments of act 2004.

At act 2006, a vertical connection well and a first contact region are formed in the substrate on opposing sides of the first avalanche well. The vertical connection well and the first contact region have the second doping type. FIGS. 7A, 7B, 9A, and 9B illustrate various views corresponding to some embodiments of act 2006.

At act 2008, the substrate is patterned to form a recess in the substrate overlying the first avalanche well. FIGS. 11A and 11B illustrate various views corresponding to some embodiments of act 2008.

At act 2010, a second avalanche well is formed in the substrate over the first avalanche well and under the recess. The second avalanche well has the first doping type. FIGS. 12A and 12B illustrate various views corresponding to some embodiments of act 2010.

At act 2012, a semiconductor layer is formed in the recess, where the semiconductor layer comprises a second material different from the first material. FIGS. 14A, 14B, 15A, and 15B illustrate various views corresponding to some embodiments of act 2012.

At act 2014, a doped cap layer is formed on the semiconductor layer, where the doped cap layer comprises the first doping type. FIGS. 16A and 16B illustrate various views corresponding to some embodiments of act 2014.

At act 2016, a doped peripheral region is formed on opposing sides of the doped cap layer. The doped peripheral region extends from the doped cap layer to the substrate and comprises the first doping type. FIGS. 17A and 17B illustrate various views corresponding to some embodiments of act 2016.

At act 2018, a plurality of conductive contacts are formed over the substrate. FIGS. 19A and 19B illustrate various views corresponding to some embodiments of act 2018.

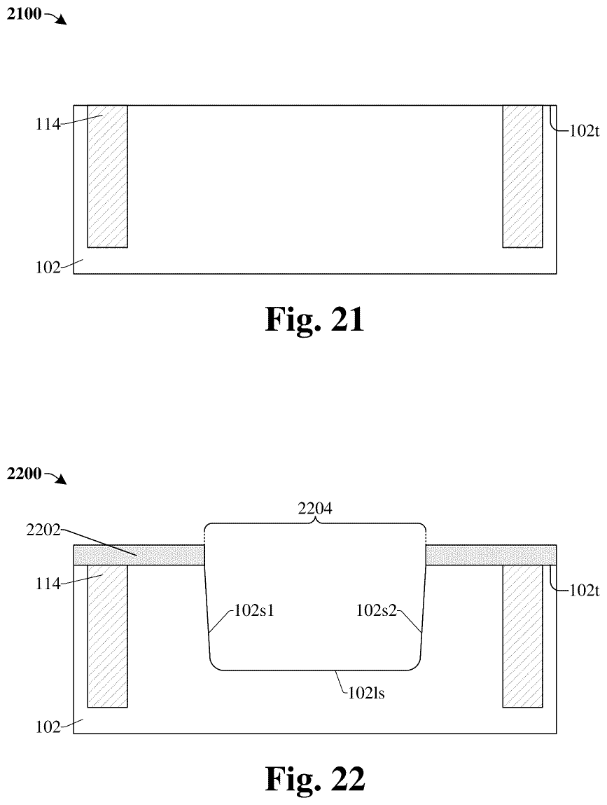

FIGS. 21-28 illustrate a series of cross-sectional views 2100-2800 of some other embodiments of a method for forming an image sensor comprising a doped cap layer over a semiconductor layer of a photodetector and a doped peripheral region adjacent to outer edges of the semiconductor layer. Although the cross-sectional views 2100-2800 shown in FIGS. 21-28 are described with reference to a method of forming the image sensor, it will be appreciated that the structures shown in FIGS. 21-28 are not limited to the method of formation but rather may stand alone separate of the method. Further, although FIGS. 21-28 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in the cross-sectional view 2100 of FIG. 21, a substrate 102 is provided and an isolation structure 114 is formed in the substrate 102. In some embodiments, the substrate 102 comprises a first material (e.g., silicon) and has a first doping type (e.g., p-type). In various embodiments, forming the isolation structure 114 includes: forming a masking layer over a top surface 102t of the substrate; etching the substrate 102 with the masking layer in place to form one or more trenches extending into the substrate 102; depositing (e.g., by CVD, PVD, ALD, or the like) one or more isolation materials (e.g., silicon dioxide, silicon nitride, silicon carbide, or the like) in the one or more trenches; and performing a planarization process (e.g., a CMP process) on the one or more isolation materials.

As shown in the cross-sectional view 2200 of FIG. 22, a recess 2204 is formed in the substrate 102. The recess 2204 is defined at least in part by opposing sidewalls 102s1, 102s2 and a lower surface 102ls of the substrate 102. In some embodiments, forming the recess 2204 includes forming a masking layer 2202 over the substrate 102 and performing an etching process (e.g., a reactive-ion etch, a plasma etch, or the like) on the substrate 102 with the masking layer 2202 in place. In various embodiments, the masking layer 2202 may be removed after the etching process.

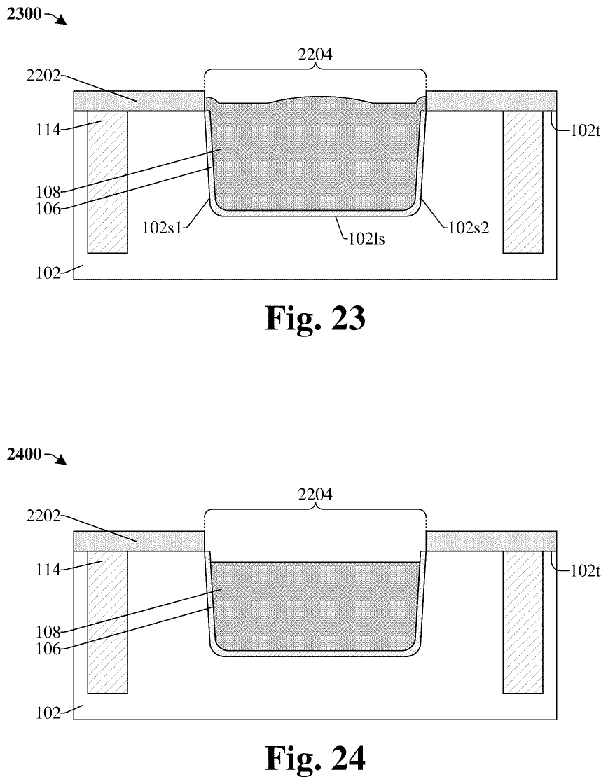

As shown in the cross-sectional view 2300 of FIG. 23, an interlayer 106 and a semiconductor layer 108 are formed in the recess 2204. The semiconductor layer 108 comprises a second material (e.g., germanium) different from the first material. The interlayer 106 and the semiconductor layer 108 may, for example, be formed by the acts illustrated and/or described in FIGS. 14A and 14B.

As shown in the cross-sectional view 2400 of FIG. 24, a top surface of the semiconductor layer 108 is planarized and/or recessed below the top surface 102t of the substrate 102. The semiconductor layer 108 may, for example, be planarized and/or recessed by the acts illustrated and/or described in FIGS. 15A and 15B.

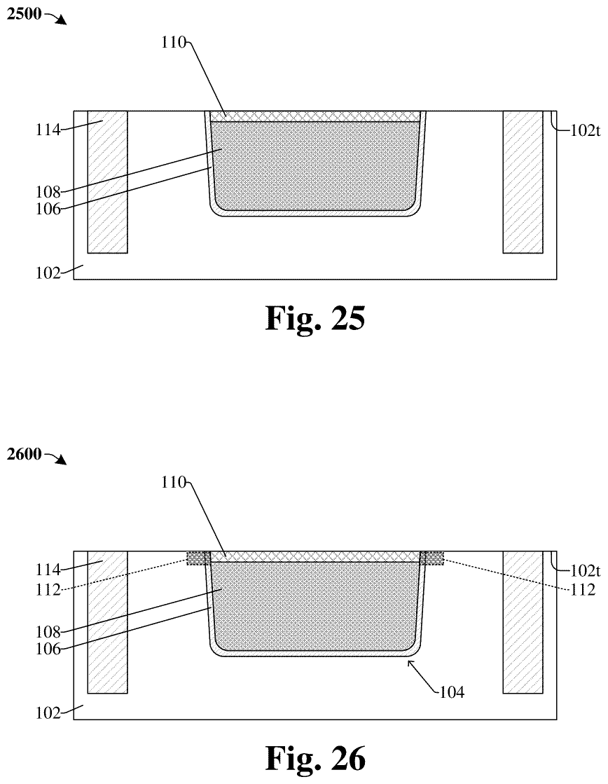

As shown in the cross-sectional view 2500 of FIG. 25, a doped cap layer 110 is formed over the semiconductor layer 108. The doped cap layer 110 may, for example, be formed by the acts illustrated and/or described in FIGS. 16A and 16B.

As shown in the cross-sectional view 2600 of FIG. 26, a doped peripheral region 112 is formed in the substrate 102 and/or interlayer 106 on opposing sides of the semiconductor layer 108. The doped peripheral region 112 may, for example, be formed by the acts illustrated and/or described in FIGS. 17A and 17B.

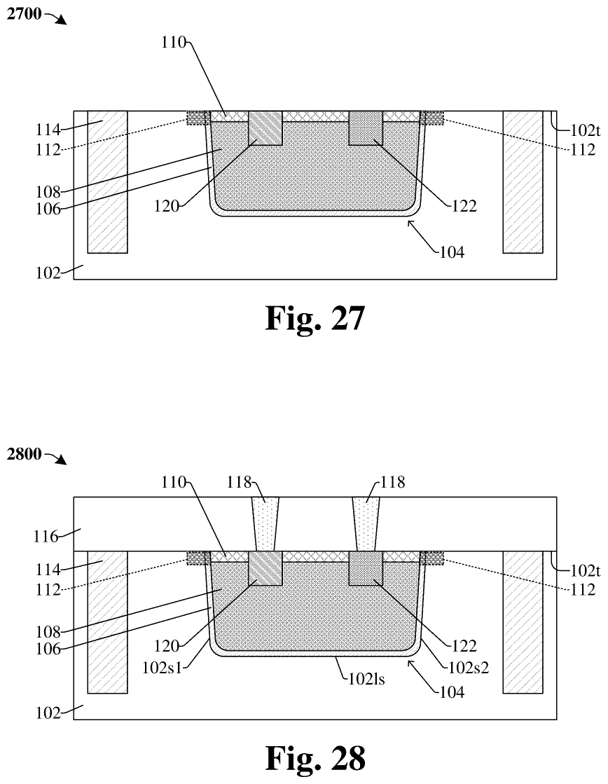

As shown in the cross-sectional view 2700 of FIG. 27, a first doped region 120 and a second doped region 122 are formed in the doped cap layer 110 and the semiconductor layer 108. In some embodiments, forming the first doped region 120 includes: forming a first implant mask over the substrate 102; performing a first ion implantation process that implants one or more first dopants (e.g., boron, gallium, indium or the like) having the first doping type (e.g., p-type) into the doped cap layer 110 and/or the semiconductor layer 108 with the first implant mask in place; and removing the first implant mask. In various embodiments, forming the second doped region 122 includes: forming a second implant mask over the substrate 102; performing a second ion implantation process that implants one or more second dopants (e.g., phosphorus, arsenic, antimony, or the like) having the second doping type (e.g., n-type) into the doped cap layer 110 and/or the semiconductor layer 108 with the second implant mask in place; and removing the second implant mask.

As shown in the cross-sectional view 2800 of FIG. 28, a dielectric structure 116 and a plurality of conductive contacts 118 are formed over the substrate 102. The dielectric structure 116 and the plurality of conductive contacts 118 may, for example, be formed by the acts illustrated and/or described in FIGS. 19A and 19B.

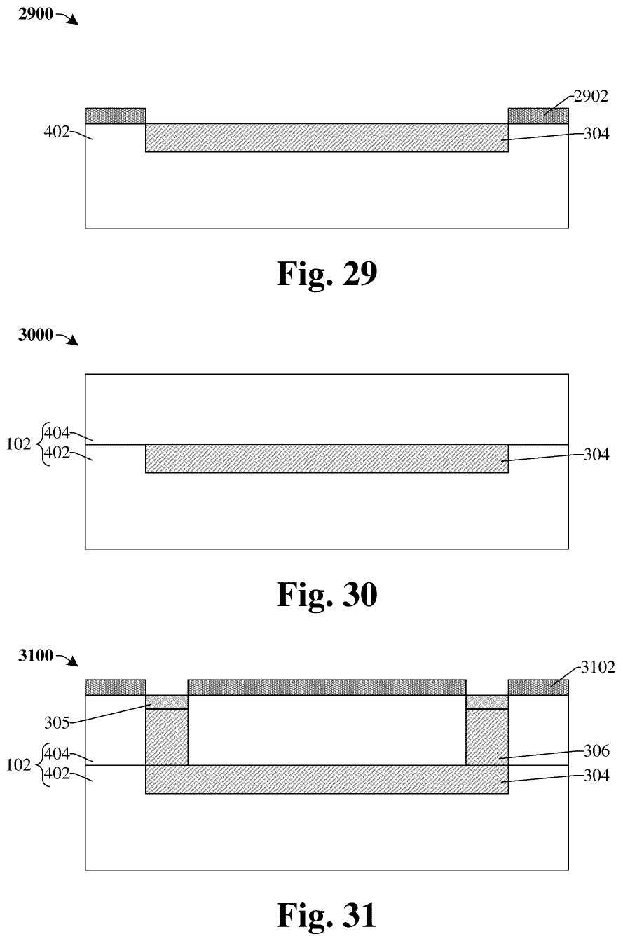

FIGS. 29-38 illustrate a series of cross-sectional views 2900-3800 of some other embodiments of a method for forming an image sensor comprising a doped cap layer over a semiconductor layer of a photodetector and a doped peripheral region adjacent to outer edges of the semiconductor layer. Although the cross-sectional views 2900-3800 shown in FIGS. 29-38 are described with reference to a method of forming the image sensor, it will be appreciated that the structures shown in FIGS. 29-38 are not limited to the method of formation but rather may stand alone separate of the method. Further, although FIGS. 29-38 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in cross-sectional view 2900 of FIG. 29, a base substrate 402 is provided and a first avalanche well 304 is formed in the base substrate 402. The base substrate 402 may, for example, be or comprise silicon, monocrystalline silicon, a silicon-on-insulator (SOI) substrate, or some other suitable semiconductor substrate material. In various embodiments, the base substrate 402 has a first doping type (e.g., p-type). In some embodiments, forming the first avalanche well 304 includes: forming a first implant mask 2902 over the base substrate 402; performing an ion implantation process that implants one or more second dopants (e.g., phosphorus, arsenic, antimony, or the like) having a second doping type (e.g., n-type) into the base substrate 402 with the first implant mask 2902 in place; and removing the first implant mask 2902.

As shown in cross-sectional view 3000 of FIG. 30, an upper substrate layer 404 is formed over the base substrate 402, thereby forming or defining a substrate 102. In some embodiments, the substrate 102 comprises the base substrate 402 and the upper substrate layer 404. The upper substrate layer 404 may, for example, be formed by MBE, CVD, VPE, LPE, or some other suitable deposition or growth process. The upper substrate layer 404 comprises a first material (e.g., silicon) and may have the first doping type (e.g., p-type).

As shown in cross-sectional view 3100 of FIG. 31, a vertical connection well 306 and a first contact region 305 are formed in the upper substrate layer 404 of the substrate 102. In some embodiments, forming the vertical connection well 306 and the first contact region 305 includes: forming a second implant mask 3102 over the upper substrate layer 404; performing a first ion implantation process to implant one or more second dopants (e.g., arsenic, antimony, phosphorus, or the like) having the second doping type (e.g., n-type) into the upper substrate layer 404 with the second implant mask 3102 in place, thereby defining or forming the vertical connection well 306; performing a second ion implantation process to implant one or more second dopants (e.g., arsenic, antimony, phosphorus, or the like) having the second doping type (e.g., n-type) into the upper substrate layer 404 with the second implant mask 3102 in place, thereby defining or forming the first contact region 305; and removing the second implant mask 3102. In some embodiments, a doping concentration of the first contact region 305 is greater than a doping concentration of the vertical connection well 306.

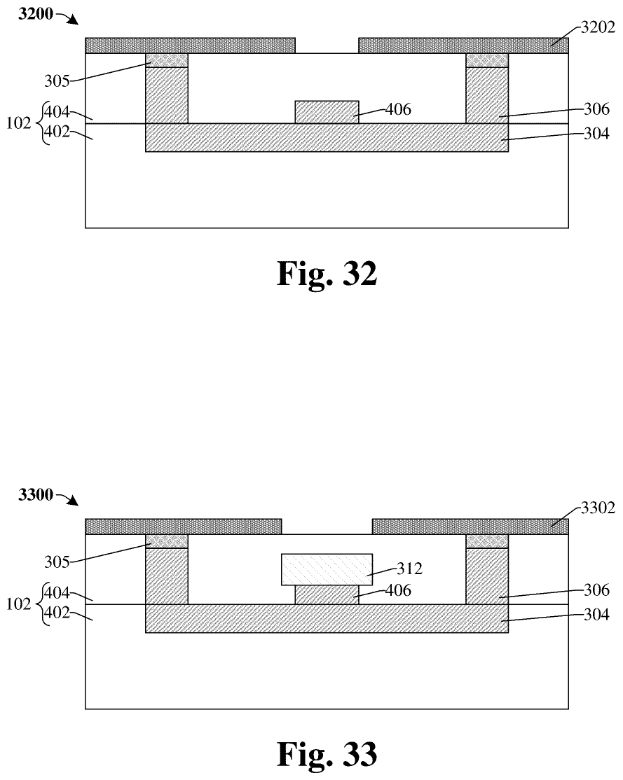

As shown in cross-sectional view 3200 of FIG. 32, an avalanche well extension region 406 is formed in the upper substrate layer 404 of the substrate 102. In some embodiments, forming the avalanche well extension region 406 includes: forming a third implant mask 3202 over the substrate 102; performing an ion implantation process to implant one or more second dopants (e.g., arsenic, antimony, phosphorus, or the like) having the second doping type (e.g., n-type) into the upper substrate layer 404 with the third implant mask 3202 in place; and removing the third implant mask 3202.

As shown in cross-sectional view 3300 of FIG. 33, a second avalanche well 312 is formed in the upper substrate layer 404 of the substrate 102. In some embodiments, forming the second avalanche well 312 includes: forming a fourth implant mask 3302 over the substrate 102; performing an ion implantation process to implant one or more first dopants (e.g., boron, gallium, indium, or the like) having the first doping type (e.g., p-type) into the upper substrate layer 404 with the fourth implant mask 3302 in place; and removing the fourth implant mask 3302.

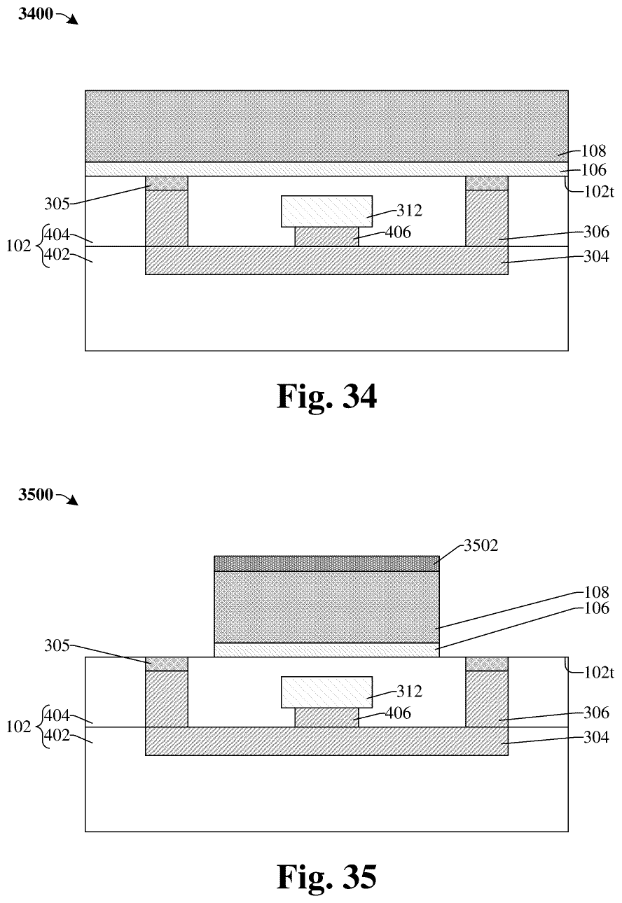

As shown in cross-sectional view 3400 of FIG. 34, an interlayer 106 and a semiconductor layer 108 are formed on a top surface 102t of the substrate 102. In some embodiments, the interlayer 106 comprises the first material (e.g., silicon). The interlayer 106 may, for example, be formed by MBE, CVD, VPE, LPE, or some other suitable deposition or growth process. The interlayer 106 may be undoped. In some embodiments, the semiconductor layer 108 comprises a second material (e.g., germanium) different from the first material (e.g., silicon). The semiconductor layer 108 may be formed on the interlayer 106 by, for example, MBE, CVD, VPE, LPE, or some other suitable deposition or growth process.

As shown in cross-sectional view 3500 of FIG. 35, a patterning process is performed on the semiconductor layer 108 and the interlayer 106. In some embodiments, the patterning process includes: forming a masking layer 3502 on the semiconductor layer 108; performing an etch process (e.g., a plasma etch, a reactive-ion etch, etc.) on the semiconductor layer 108 and the interlayer 106; and removing the masking layer 3502.

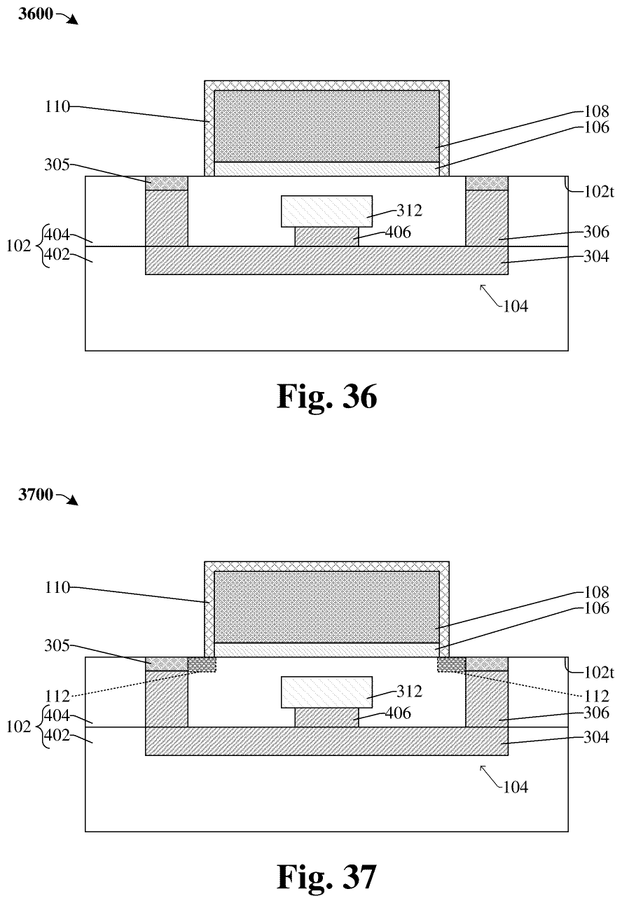

As shown in cross-sectional view 3600 of FIG. 36, a doped cap layer 110 is formed over the semiconductor layer 108 and the substrate 102. The doped cap layer 110 is formed over the semiconductor layer 108 and the substrate 102 by an epitaxial process (e.g., MBE, CVD, VPE, LPE, etc.). In various embodiments, the doped cap layer 110 may be formed by the epitaxial process illustrated and/or described in FIGS. 16A and 16B. In various embodiments, the doped cap layer 110 may be formed such that the doped cap layer 110 grows on the semiconductor layer 108 and the interlayer 106, but not the substrate 102. For example, a masking layer may be formed over the top surface 102t of the substrate 102 before forming the doped cap layer 110, such that the doped cap layer 110 does not grow on the masking layer. The masking layer is subsequently removed after forming the doped cap layer 110. In further embodiments, the doped cap layer 110 is formed across the top surface 102t of the substrate 102. In such embodiments, a patterning process is performed after forming the doped cap layer 110 to remove the doped cap layer 110 from over the substrate 102 in regions offset from the semiconductor layer 108.

As shown in cross-sectional view 3700 of FIG. 37, a doped peripheral region 112 is formed in the upper substrate layer 404 of the substrate 102 and on opposing sides of the semiconductor layer 108. The doped peripheral region 112 may, for example, be formed by the acts illustrated and/or described in FIGS. 17A and 17B. The doped peripheral region 112 may, for example, be formed in the interlayer 106, such that the doped peripheral region 112 is configured as illustrated and/or described in FIG. 4B.

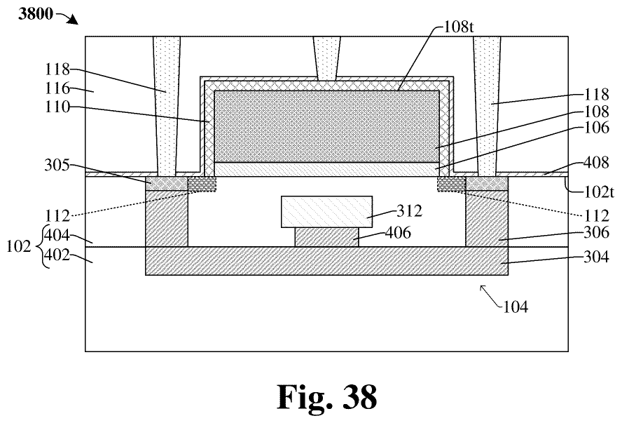

As shown in cross-sectional view 3800 of FIG. 38, an etch stop layer 408, a dielectric structure 116, and a plurality of conductive contacts 118 are formed over the substrate 102. The etch stop layer 408 is formed over the substrate 102 by, for example, a CVD process, a PVD process, an ALD process, or some other suitable growth or deposition process. The dielectric structure 116 and the plurality of conductive contacts 118 may, for example, be formed by the acts illustrated and/or described in FIGS. 19A and 19B.

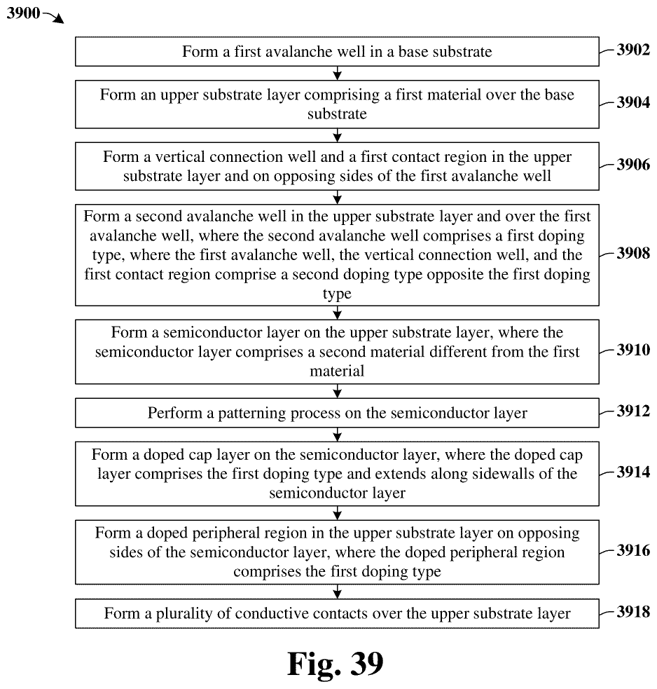

FIG. 39 illustrates a block diagram 3900 of some embodiments of the method of FIGS. 29-38. Although the block diagram 3900 is illustrated and/or described as a series of acts or events, it will be appreciated that the illustrated ordering of such acts or events is not to be interpreted in a limiting sense. For example, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 3902, a first avalanche well is formed in a base substrate. FIG. 29 illustrates a cross-sectional view 2900 corresponding to some embodiments of act 3902.

At act 3904, an upper substrate layer comprising a first material is formed over the base substrate. FIG. 30 illustrates a cross-sectional view 3000 corresponding to some embodiments of act 3904.

At act 3906, a vertical connection well and a first contact region are formed in the upper substrate layer and on opposing sides of the first avalanche well. FIG. 31 illustrates a cross-sectional view 3100 corresponding to some embodiments of act 3906.

At act 3908, a second avalanche well is formed in the upper substrate layer and over the first avalanche well. The second avalanche well comprises a first doping type. The first avalanche well, the vertical connection well, and the first contact region comprise a second doping type opposite the first doping type. FIG. 33 illustrates a cross-sectional view 3300 corresponding to some embodiments of act 3908.

At act 3910, a semiconductor layer is formed on the upper substrate layer, where the semiconductor layer comprises a second material different from the first material. FIG. 34 illustrates a cross-sectional view 3400 corresponding to some embodiments of act 3910.

At act 3912, a patterning process is performed on the semiconductor layer. FIG. 35 illustrates a cross-sectional view 3500 corresponding to some embodiments of act 3912.

At act 3914, a doped cap layer is formed on the semiconductor layer, where the doped cap layer comprises the first doping type and extends along sidewalls of the semiconductor layer. FIG. 36 illustrates a cross-sectional view 3600 corresponding to some embodiments of act 3914.

At act 3916, a doped peripheral region is formed in the upper substrate layer on opposing sides of the semiconductor layer, where the doped peripheral region comprises the first doping type. FIG. 37 illustrates a cross-sectional view 3700 corresponding to some embodiments of act 3916.

At act 3918, a plurality of conductive contacts are formed over the upper substrate layer. FIG. 38 illustrates a cross-sectional view 3800 corresponding to some embodiments of act 3918.

Accordingly, in some embodiments, the present disclosure relates to an image sensor comprising a semiconductor layer of a photodetector within and/or on a substrate, a doped cap layer on the semiconductor layer, and a doped peripheral region in the substrate and adjacent to outer edges of the semiconductor layer.

In some embodiments, the present application provides an image sensor include: a substrate comprising a first material; a semiconductor layer on the substrate and comprising a second material different from the first material; a doped cap layer on a top surface of the semiconductor layer and comprising a first doping type; and a doped peripheral region in the substrate and on opposing sides of the semiconductor layer, wherein the doped peripheral region comprises the first doping type.

In some embodiments, the present application provides a method for forming an image sensor, including: forming an interlayer on a substrate, wherein the substrate comprises a first material having a first bandgap; forming a semiconductor layer on the interlayer, wherein the semiconductor layer comprises a second material having a second bandgap less than the first bandgap; forming a doped cap layer on a top surface of the semiconductor layer, wherein the doped cap layer comprises one or more first dopants and continuously extends between opposing sidewalls of the semiconductor layer; and forming a doped peripheral region in the interlayer and the substrate, wherein the doped peripheral region is adjacent to opposing edges of the doped cap layer and comprises the one or more first dopants, wherein in top view the doped peripheral region is ring-shaped.

In some embodiments, the present application provides another method for forming an image sensor, including: forming a semiconductor layer on a substrate, wherein the substrate comprises a first material and the semiconductor layer comprises a second material different from the first material; forming a doped cap layer on the semiconductor layer, wherein the doped cap layer is formed by an epitaxial layer and is in-situ doped with one or more first dopants having a first doping type; and performing an annealing process to form a doped peripheral region in the substrate and on opposing sides of the doped cap layer, wherein the doped peripheral region comprises the first doping type, and wherein the annealing process drives the one or more first dopants from the doped cap layer into the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor, comprising:
a substrate comprising a first material;
a semiconductor layer on the substrate and comprising a second material different from the first material;
a doped cap layer on a top surface of the semiconductor layer and comprising a first doping type; and
a doped peripheral region in the substrate and on opposing sides of the semiconductor layer, wherein the doped peripheral region comprises the first doping type.

2. The image sensor of claim 1, wherein the doped peripheral region continuously laterally wraps around an outer perimeter of the semiconductor layer and is laterally offset from a middle region of the semiconductor layer.

3. The image sensor of claim 1, further comprising:
a doped region in the semiconductor layer and under the doped cap layer, wherein the doped region comprises the first doping type, wherein a doping concentration of the doped region is less than a doping concentration of the doped cap layer and a doping concentration of the doped peripheral region.

4. The image sensor of claim 1, wherein the substrate comprises opposing sidewalls defining a recess, wherein the semiconductor layer is arranged in the recess and the top surface of the semiconductor layer is below a top surface of the substrate, wherein the doped cap layer extends along the top surface of the semiconductor layer between the opposing sidewalls of the substrate, wherein the doped peripheral region continuously laterally extends from an outer sidewall of the doped cap layer in a direction away from the semiconductor layer.

5. The image sensor of claim 4, further comprising:
an interlayer arranged between the semiconductor layer and the substrate, wherein the interlayer comprises the first material, and wherein the doped peripheral region extends through a thickness of the interlayer.

6. The image sensor of claim 4, wherein a vertical distance between a bottom of the doped peripheral region and the top surface of the substrate is greater than a thickness of the doped cap layer.

7. The image sensor of claim 1, wherein the doped peripheral region continuously laterally extends from an outer sidewall of the doped cap layer to a first point in a direction away from the semiconductor layer, wherein a peak doping concentration of the doped peripheral region is closer to the outer sidewall of the doped cap layer than the first point.

8. The image sensor of claim 1, wherein a bottom surface of the semiconductor layer is vertically offset from a top surface of the substrate by a non-zero distance, wherein the doped cap layer extends along opposing sidewalls of the semiconductor layer, and wherein the doped peripheral region underlies the doped cap layer.

9. The image sensor of claim 1, further comprising:
one or more contact regions arranged in the substrate and adjacent to the semiconductor layer; and
a well region arranged in the substrate and under the one or more contact regions, wherein the one or more contact regions and the well region comprise a second doping type opposite the first doping type, wherein a doping concentration of the one or more contact regions is less than a doping concentration of the doped cap layer and is greater than a doping concentration of the well region.

10. The image sensor of claim 9, wherein the doped peripheral region extends along a side of an individual contact region in the one or more contact regions.

11. A method for forming an image sensor, comprising:
forming an interlayer on a substrate, wherein the substrate comprises a first material having a first bandgap;
forming a semiconductor layer on the interlayer, wherein the semiconductor layer comprises a second material having a second bandgap less than the first bandgap;
forming a doped cap layer on a top surface of the semiconductor layer, wherein the doped cap layer comprises one or more first dopants and continuously extends between opposing sidewalls of the semiconductor layer; and
forming a doped peripheral region in the interlayer and the substrate, wherein the doped peripheral region is adjacent to opposing edges of the doped cap layer and comprises the one or more first dopants, wherein in top view the doped peripheral region is substantially ring-shaped.

12. The method of claim 11, wherein a doping concentration of the doped peripheral region is less than a doping concentration of the doped cap layer.

13. The method of claim 11, wherein the doped cap layer is formed by an epitaxial process and is in-situ doped with the one or more first dopants, and wherein the doped peripheral region is formed by an annealing process that drives the one or more first dopants from the doped cap layer into the interlayer and the substrate.

14. The method of claim 11, wherein a width of the doped peripheral region along a sidewall of the doped cap layer is greater than a height of the doped peripheral region, wherein the height of the doped peripheral region is greater than a thickness of the interlayer and a thickness of the doped cap layer.

15. The method of claim 14, wherein a doping concentration of the doped peripheral region decreases across the width of the doped peripheral region in a direction away from the sidewall of the doped cap layer.

16. The method of claim 11, wherein the interlayer and the doped cap layer comprise the first material, wherein the interlayer below the doped peripheral region is undoped.

17. The method of claim 11, wherein a bottom surface of the semiconductor layer is above a top surface of the substrate, wherein the doped cap layer extends along outer sidewalls of the semiconductor layer and outer sidewalls of the interlayer, wherein the doped peripheral region extends from an inner sidewall of the interlayer to the substrate, and wherein at least a portion of the doped peripheral region underlies the bottom surface of the semiconductor layer.

18. A method for forming an image sensor, comprising:
forming a semiconductor layer on a substrate, wherein the substrate comprises a first material and the semiconductor layer comprises a second material different from the first material;
forming a doped cap layer on the semiconductor layer, wherein the doped cap layer is formed by an epitaxial layer and is in-situ doped with one or more first dopants having a first doping type; and
performing an annealing process to form a doped peripheral region in the substrate and on opposing sides of the doped cap layer, wherein the doped peripheral region comprises the first doping type, and wherein the annealing process drives the one or more first dopants from the doped cap layer into the substrate.

19. The method of claim 18, wherein the annealing process is performed at a temperature within a range of approximately 700 to 900 degrees Celsius and has a duration of 60 seconds or less.

20. The method of claim 18, further comprising:
forming one or more well regions in the substrate and on opposing sides of the semiconductor layer, wherein the one or more well regions comprise a second doping type opposite the first doping type; and
forming one or more contact regions in the substrate and over the one or more well regions, wherein the one or more contact regions comprise the second doping type, and wherein the one or more well regions and the one or more contact regions are formed by one or more ion implantation processes.
